(19) United States
(12) Patent Application Publication
(10) Pub. No.: US 2023/0207608 A1
(43) Pub. Date: Jun. 29, 2023

(54) DISPLAY DEVICE

(71) Applicant: Samsung Display Co., LTD., Yongin-si, Gyeonggi-do (KR)

(72) Inventors: Han Su KIM, Seoul (KR); Eun A YANG, Yongin-si Gyeonggi-do (KR); Jong Hyuk KANG, Suwon-si Gyeonggi-do (KR); Hyun Min CHO, Seoul (KR)

(73) Assignee: Samsung Display Co., LTD., Yongin-si, Gyeonggi-do (KR)

(21) Appl. No.: 17/923,509

(22) PCT Filed: Apr. 1, 2021
(86) PCT No.: PCT/KR2021/004081

§ 371 Date: Nov. 4, 2022

(30) Foreign Application Priority Data
May 4, 2020 (KR) 10-2020-0053258

(51) Int. Cl. H01L 27/15; H01L 33/00; H01L 33/24; H01L 33/44

(52) U.S. Cl. CPC H01L 27/156; H01L 33/005; H01L 33/24; H01L 33/44

(57) ABSTRACT

A display device includes: a pixel region including a plurality of alignment areas and a non-alignment area adjacent to the plurality of alignment areas; a plurality of electrodes extending in a direction and be spaced apart from each other in the pixel region; a plurality of light-emitting elements disposed between the plurality of electrodes in the plurality of alignment areas and including at least one end of the plurality of light-emitting elements disposed on one of the plurality of electrodes; and an alignment-inducing layer including a first part disposed in the non-alignment area.

### CROSS REFERENCE TO RELATED APPLICATION(S)

This application is a national entry of International Application No. PCT/KR2021/004081, filed on Apr. 1, 2021, which claims under 35 U.S.C. §§ 119(a) and 365(b) priority to and benefits of Korean Patent Application No. 10-2020-0053258, filed on May 4, 2020, in the Korean Intellectual Property Office (KIPO), the entire content of which are incorporated herein by reference.

### BACKGROUND

### 1. Technical Field

Embodiments relate to a display device.

### 2. Description of the Related Art

The importance of display devices has steadily increased with the development of multimedia technology. Various types of display devices such as an organic light emitting display (OLED), a liquid crystal display (LCD) and the like have been used in various fields.

A display device is a device for displaying an image, and includes a display panel, such as an organic light emitting display panel or a liquid crystal display panel. The light emitting display panel may include light emitting elements, e.g., light emitting diodes (LED). The examples of the light emitting diode include an organic light emitting diode (OLED) by using an organic material as a fluorescent material and an inorganic light emitting diode by using an inorganic material as a fluorescent material.

### SUMMARY

To address the aforementioned problems, embodiments provide a display device capable of guiding light-emitting elements to be arranged at a certain location by forming an alignment-inducing layer.

However, embodiments of the disclosure are not limited to those set forth herein. The above and other embodiments will become more apparent to one of ordinary skill in the art to which the disclosure pertains by referencing the detailed description of the disclosure given below.

According to an embodiment, a display device may include a pixel region including a plurality of alignment areas and a non-alignment area adjacent to the plurality of alignment areas, a plurality of electrodes extending in a direction in the pixel region, the plurality of electrodes spaced apart from each other, a plurality of light-emitting elements disposed between the plurality of electrodes in the plurality of alignment areas, at least one end portion of each of the plurality of light-emitting elements is disposed on one of the plurality of electrodes, and an alignment-inducing layer including a first part disposed in the non-alignment area.

The first part of the alignment-inducing layer may include a hydrophobic material, and the first part may surround the plurality of alignment areas.

The display device may further include a plurality of connecting electrodes disposed in the plurality of alignment areas and overlapping the plurality of electrodes and end portions of the plurality of light-emitting elements.

The first part of the alignment-inducing layer may partially cover electrodes disposed on outermost sides of the pixel region and extending along the direction.

The plurality of alignment areas may include first and second alignment areas that are spaced apart from each other in the direction, and the alignment-inducing layer may include extension parts disposed between the first and second alignment areas.

A number of light-emitting elements disposed in the first and second alignment areas may be greater than a number of light-emitting elements disposed between the first and second alignment areas.

The extension parts of the alignment-inducing layer between the first and second alignment areas may be spaced apart from each other.

The alignment-inducing layer may further include a second part including a hydrophilic material, and the second part of the alignment-inducing layer may be further disposed in the plurality of alignment areas.

The plurality of light-emitting elements may be disposed directly on the second part, in the plurality of alignment areas.

The display device may further include a plurality of first banks disposed in the pixel region, the plurality of first banks being spaced apart from each other and overlapping the plurality of electrodes, wherein the alignment-inducing layer may surround the first banks.

The display device may further include a second bank surrounding the pixel region.

The plurality of alignment areas may be spaced apart from each other in a region surrounded by the second bank, the alignment-inducing layer may be disposed between the plurality of alignment areas, and the plurality of light-emitting elements may be disposed in the plurality of alignment areas, and light-emitting elements in different alignment areas emit light of different wavelengths.

According to an embodiment, a display device may include a substrate, a plurality of first banks disposed on the substrate and spaced apart from each other, a plurality of electrodes disposed on the first banks and spaced apart from each other, an alignment-inducing layer disposed on the substrate, the alignment-inducing layer including a first part disposed in regions other than between the plurality of electrodes, and a plurality of light-emitting elements disposed between the plurality of electrodes, each of the plurality of light-emitting elements including an end portion disposed on the plurality of electrodes, wherein the first part of the alignment-inducing layer does not overlap the plurality of light-emitting elements.

The first part of the alignment-inducing layer may include a hydrophobic material.

The first part of the alignment-inducing layer may cover outer sides of electrodes on outermost sides of the substrate.

The alignment-inducing layer may further include a second part including a hydrophilic material, the second part may be disposed between the plurality of electrodes, and the plurality of light-emitting elements may overlap the second part.

The display device may further include a first insulating layer overlapping the plurality of electrodes, wherein the alignment-inducing layer may be disposed on the first insulating layer.

The display device may further include a second insulating layer disposed between the plurality of electrodes and overlapping the plurality of light-emitting elements.

The first insulating layer and the alignment-inducing layer may expose upper surfaces of the plurality of electrodes on the first banks.

The display device may further include a plurality of connecting electrodes in contact with the exposed upper surfaces of the plurality of electrodes and an end portion of each of the plurality of light-emitting elements.

According to embodiments, a display device may include an alignment-inducing layer and may thus densely arrange a plurality of light-emitting elements at a certain location. Each pixel or subpixel of the display device includes an alignment area where the plurality of light-emitting elements are densely arranged due to the alignment-inducing layer and a non-alignment area adjacent to the alignment-inducing layer. As the alignment-inducing layer is formed, the loss amounts of light-emitting elements may be minimized, and degree of emission concentration may be improved by densely arranging the light-emitting elements at a certain location.

The effects according to the embodiments are not limited by the contents described as examples above, and more various effects are included in this disclosure.

### BRIEF DESCRIPTION OF DRAWINGS

FIG. 1 is a schematic plan view of a display device according to an embodiment;

FIG. 2 is a schematic plan view of a pixel of the display device according to an embodiment;

FIG. 3 is a schematic cross-sectional view taken along lines III-IIIa′, IIIb-IIIb′, and IIIc-IIIc′ of FIG. 2;

FIG. 4 is a schematic cross-sectional view taken along line IV-IV′ of FIG. 2;

FIG. 5 is a partial schematic cross-sectional view of a display device according to an embodiment;

FIG. 6 is a schematic view of a light-emitting element according to an embodiment;

FIGS. 7 through 12 are schematic cross-sectional views illustrating the method of manufacturing a display device according to an embodiment;

FIG. 13 is a schematic plan view of a subpixel of a display device according to an embodiment;

FIG. 14 is a schematic plan view of a subpixel of a display device according to an embodiment;

FIG. 15 is a schematic cross-sectional view taken along line V-V′ of FIG. 14;

FIGS. 16 through 18 are schematic cross-sectional views illustrating a method of manufacturing the display device of FIG. 14;

FIG. 19 is a schematic plan view of a subpixel of a display device according to an embodiment;

FIG. 20 is a schematic cross-sectional view taken along line X1-X1′ of FIG. 19;

FIG. 21 is a schematic cross-sectional view taken along line X2-X2′ of FIG. 19;

FIG. 22 is a schematic cross-sectional view illustrating a method of manufacturing the display device of FIG. 19;

FIG. 23 is a schematic plan view of a subpixel of a display device according to an embodiment;

FIG. 24 is a schematic cross-sectional view taken along lines X3-X3′, X4-X4′, and X5-X5′ of FIG. 23;

FIG. 25 is a schematic plan view of a subpixel of a display device according to an embodiment;

FIG. 26 is a schematic plan view of a subpixel of a display device according to an embodiment;

FIG. 27 is a schematic plan view of a pixel of a display device according to an embodiment; and

FIG. 28 is a schematic plan view of a subpixel of a display device according to an embodiment.

### DETAILED DESCRIPTION OF THE EMBODIMENTS

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it may be directly on the other layer or substrate, or intervening layers may also be present. The same reference numbers indicate the same components throughout the specification. When an element, such as a layer, is referred to as being “connected to,” or “coupled to” another element or layer, it may be directly connected to, or coupled to the other element or layer or intervening elements or layers may be present. When, however, an element or layer is referred to as being “directly connected to,” or “directly coupled to” another element or layer, there are no intervening elements or layers present. To this end, the term “connected” may refer to physical, electrical, and/or fluid connection, with or without intervening elements.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, in case that the apparatus in the drawings is turned over, elements described as “below” or “beneath” other elements or features would then be oriented “above” the other elements or features. Thus, the term “below” may encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing certain embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. For example, the second element could also be termed the first element.

Hereinafter, embodiments will be described with reference to the accompanying drawings.

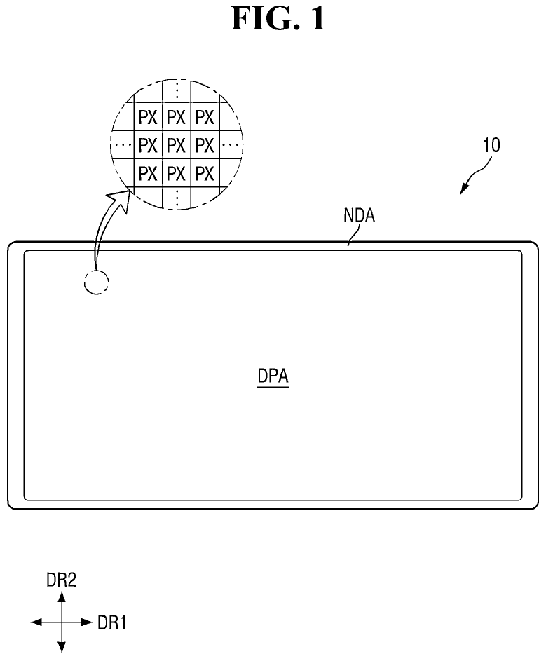

FIG. 1 is a schematic plan view of a display device according to an embodiment.

Referring to FIG. 1, a display device 10 may display a moving or still image. The display device 10 may refer to nearly all types of electronic devices that provide a display screen. Examples of the display device 10 may include a television (TV), a notebook computer, a monitor, a billboard, an Internet-of-Things (IoT) device, a mobile phone, a smartphone, a tablet personal computer (PC), an electronic watch, a smartwatch, a watchphone, a head-mounted display (HMD), a mobile communication terminal, an electronic notepad, an electronic book (e-book), a portable multimedia player (PMP), a navigation device, a gaming console, a digital camera, a camcorder, and the like.

The display device 10 may include a display panel that provides a display screen. Examples of the display panel of the display device 10 include an inorganic light-emitting diode (LED) display panel, an organic light-emitting diode (OLED) display panel, a quantum-dot light-emitting diode (QLED) display panel, a plasma display panel (PDP), a field-emission display (FED) panel, and the like. The display panel of the display device 10 will hereinafter be described as being, for example, an ILED display panel, but embodiments are not limited thereto. For example, various other display panels may be also applicable to the display panel of the display device 10.

The shape of the display device 10 may vary. For example, the display device 10 may have a rectangular shape that extends longer in a horizontal direction than in a vertical direction, a rectangular shape that extends longer in the vertical direction than in the horizontal direction, a square shape, a tetragonal shape with rounded corners, a non-tetragonal polygonal shape, or a circular shape (e.g., in a plan view). The shape of a display area DPA of the display device 10 may be similar to the shape of the display device 10. FIG. 1 illustrates that the display device 10 and the display area DPA both have a rectangular shape that extends relatively long in a horizontal direction (e.g., in a plan view).

The display device 10 may include the display area DPA and a non-display area NDA. The display area DPA may be an area in which an image is displayed, and the non-display area NDA may be an area in which an image is not displayed. The display area DPA may also be referred to as an active area, and the non-display area NDA may also be referred to as an inactive area. The display area DPA may occupy or cover the middle part of the display device 10.

The display area DPA may include pixels PX. The pixels PX may be arranged in a row direction and a column direction. Each of the pixels PX may have a rectangular or square shape in a plan view, but embodiments are not limited thereto. In another example, each of the pixels PX may have a rhombus shape having sides inclined with respect to a certain direction. The pixels PX may be alternately arranged in a stripe fashion or a PenTile® fashion. Each of the pixels PX may include one or more light-emitting elements 30, which emit light of a certain wavelength band.

The non-display area NDA may be disposed around the display area DPA. The non-display area NDA may surround the entire display area DPA or part of the display area DPA. The display area DPA may have a rectangular shape, and the non-display area NDA may be disposed adjacent to four sides of the display area DPA. The non-display area NDA may form the bezel of the display device 10. Lines or circuit drivers included in the display device 10 may be disposed in the non-display area NDA, or external devices may be mounted in the non-display area NDA.

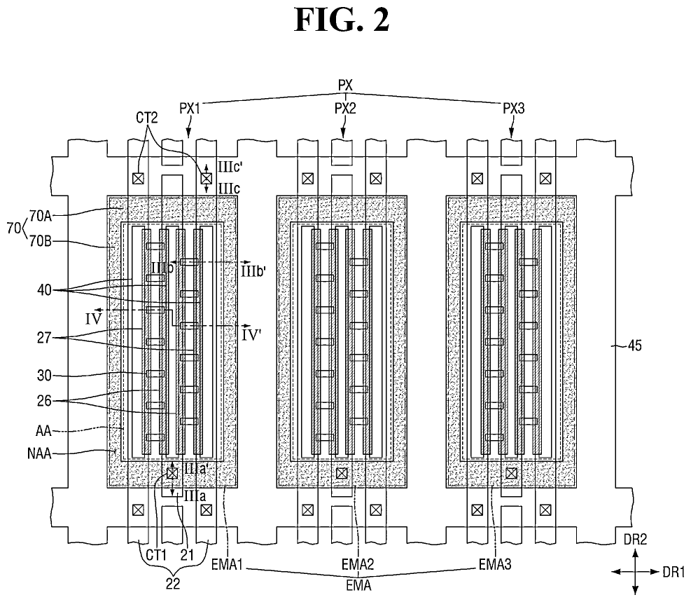

FIG. 2 is a schematic plan view of a pixel of the display device according to an embodiment.

Referring to FIG. 2, each of pixels PX may include subpixels PXn (where n is an integer of 1 to 3). For example, a pixel PX may include first, second, and third subpixels PX1, PX2, and PX3. The subpixels PXn may form pixel areas in the display area DPA. The first subpixel PX1 may emit first-color light, the second subpixel PX2 may emit second-color light, and the third subpixel PX3 may emit third-color light. The first-color light, the second-color light, and the third-color light may be blue light, green light, and red light, respectively, but embodiments are not limited thereto. In another example, the subpixels PXn may emit light of the same color. FIG. 2 illustrates that the pixel PX may include three subpixels PXn, but embodiments are not limited thereto. In another example, the pixel PX may include more than three subpixels PXn.

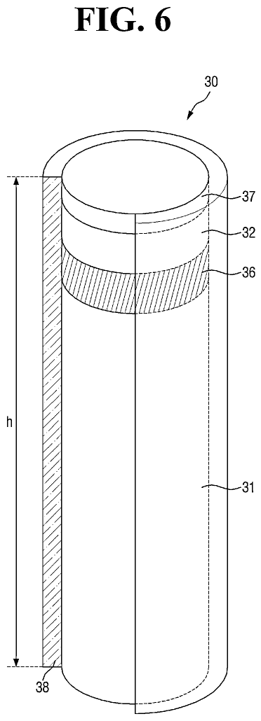

The subpixels PXn may include areas defined as emission areas EMA. The first subpixel PX1 may include a first emission area EMA1, the second subpixel PX2 may include a second emission area EMA2, and the third subpixel PX3 may include a third emission area EMA3. Each of the emission areas EMA may be defined as an area where light-emitting elements 30 emit light of a certain wavelength band. The light-emitting elements 30 may include active layers (e.g., “36” of FIG. 6), and the active layers 36 may emit light of a certain wavelength band without any directivity. Light emitted by the active layers 36 of the light-emitting elements 30 may be emitted through sides (e.g., opposite sides) of each of the light-emitting elements 30. Each of the emission areas EMA may include an area where the light-emitting elements 30 are disposed and may also include an area around the light-emitting elements 30 that outputs light emitted by the light-emitting elements 30.

However, embodiments are not limited thereto. Each of the emission areas EMA may include an area that outputs light, which is emitted by the light-emitting elements 30 and then reflected or refracted from other elements. The light-emitting elements 30 may be disposed in each of the subpixels PXn. For example, the emission areas EMA may include an area where the light-emitting elements 30 are disposed and an area surrounding the light-emitting elements 30.

For example, each of the subpixels PXn of the display device 10 may include a non-emission area, which is defined as an area other than the emission areas EMA. The non-emission area may be an area where the light-emitting elements 30 are not disposed and may not output light by blocking or absorbing light emitted by the light-emitting elements 30.

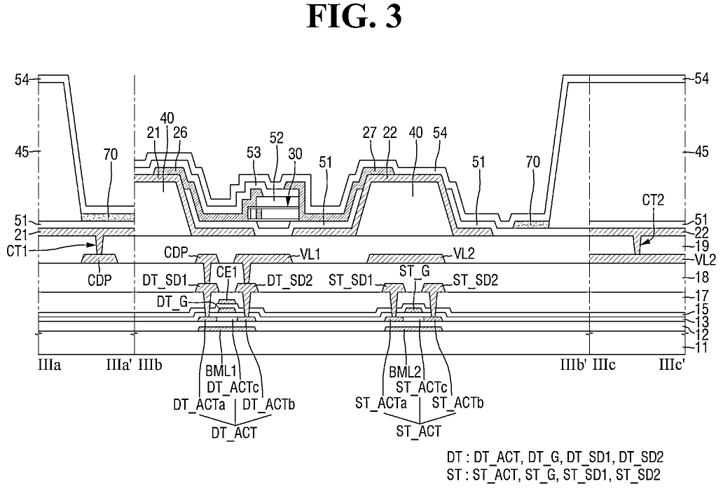

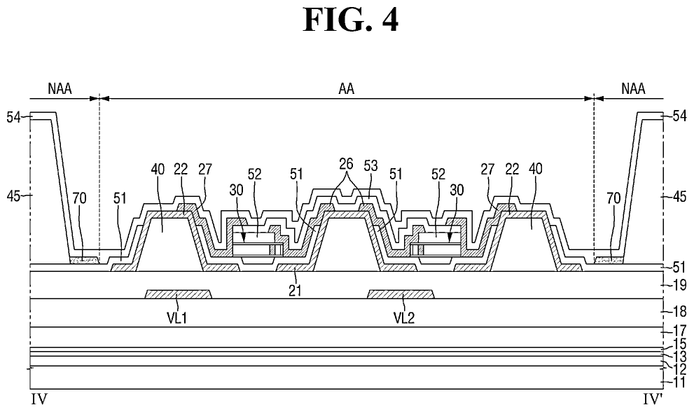

FIG. 3 is a schematic cross-sectional view taken along lines IIIa-IIIa′, IIIb-IIIb′, and IIIc-IIIc′ of FIG. 2. FIG. 4 is a schematic cross-sectional view taken along line IV-IV′ of FIG. 2. FIGS. 3 and 4 illustrate schematic cross-sectional views of the first subpixel PX1 of FIG. 2, which, however, may also be applicable to other pixels PX or other subpixels PXn. FIGS. 3 and 4 illustrate schematic cross-sectional views taken from an end portion to the other end portion of a light-emitting element 30 in the first subpixel PX1.

Referring to FIGS. 3 and 4 and further to FIG. 2, the display device 10 may include a circuit element layer and a display element layer, which are disposed on a first substrate 11. A semiconductor layer, conductive layer, and insulating layers may be disposed on the first substrate 11 and may form the circuit element layer and the display element layer. The conductive layers may include a second conductive layer, a third conductive layer, a fourth conductive layer, a fifth conductive layer, electrodes 21 and 22, and connecting electrodes 26 and 27. The insulating layers may include a buffer layer 12, a first gate insulating layer 13, a first passivation layer 15, a first interlayer insulating layer 17, a second interlayer insulating layer 18, the first planarization layer 19, a first insulating layer 51, a second insulating layer 52, a third insulating layer 53, and a fourth insulating layer 54.

Specifically, the first substrate 11 may be an insulating substrate. The first substrate 11 may be formed of an insulating material such as glass, quartz, or a polymer resin. The first substrate 11 may be a rigid substrate or may be a flexible substrate that is bendable, foldable, or rollable.

A first conductive layer may be disposed on the first substrate 11. The first conductive layer may include lower metal layers BML1 and BML2, and the lower metal layers BML1 and BML2 may include first and second lower metal layers BML1 and BML2. The first and second lower metal layers BML1 and BML2 may overlap at least a first active material layer DT_ACT of the driving transistor DT and a second active material layer ST_ACT of the switching transistor ST, respectively. The lower metal layers BML1 and BML2 may include a material capable of blocking light and may prevent light from being incident upon the first and second active material layers DT_ACT and ST_ACT. For example, the first and second lower metal layers BML1 and BML2 may be formed of an opaque metal material capable of blocking the transmission of light. However, embodiments are not limited thereto. In another example, the lower metal layers BML1 and BML2 may be omitted.

The buffer layer 12 may include the lower metal layers BML1 and BML2 and may be disposed on the entire surface of the first substrate 11. The buffer layer 12 may be formed on the first substrate 11 to protect the driving and switching transistors DT and ST from moisture that may penetrate the first substrate 11, which is susceptible to moisture, and may perform a surface planarization function. The buffer layer 12 may include inorganic layers that are alternately stacked. For example, the buffer layer 12 may be formed as a double layer or a multilayer in which inorganic layers including at least one of silicon oxide (SiOₓ), silicon nitride (SiNₓ), and silicon oxynitride (SiOₓN_{y}) are alternately stacked.

The semiconductor layer may be disposed on the buffer layer 12. The semiconductor layer may include the first active material layer DT_ACT of the driving transistor DT and the second active material layer ST_ACT of the switching transistor ST. The first active material layer DT_ACT of the driving transistor DT and the second active material layer ST_ACT of the switching transistor ST may partially overlap gate electrodes DT_G and ST_G of the second conductive layer.

In an embodiment, the semiconductor layer may include polycrystalline silicon, monocrystalline silicon, or an oxide semiconductor. For example, the polycrystalline silicon may be formed by crystallizing amorphous silicon. In a case where the semiconductor layer includes polycrystalline silicon, the first active material layer DT_ACT may include a first doped region DT_ACTa, a second doped region DT_ACTb, and a first channel region DT_ACTc. The first channel region DT_ACTc may be disposed between the first and second doped regions DT_ACTa and DT_ACTb. The second active material layer ST_ACT may include a third doped region ST_ACTa, a fourth doped region ST_ACTb, and a second channel region ST_ACTc. The second channel region ST_ACTc may be disposed between the third and fourth doped regions ST_ACTa and ST_ACTb. The first, second, third, and fourth doped regions DT_ACTa, DT_ACTb, ST_ACTa, and ST_ACTb may be parts of the first or second active material layer DT_ACT or ST_ACT that are doped with impurities.

In an embodiment, the first and second active material layers DT_ACT and ST_ACT may include an oxide semiconductor. For example, the doped regions of each of the first and second active material layers DT_ACT and ST_ACT may be conductor regions. The oxide semiconductor may be an oxide semiconductor containing indium (In). In some embodiments, the oxide semiconductor may be indium-tin oxide (ITO), indium-zinc oxide (IZO), indium-gallium oxide (IGO), indium-zinc-tin oxide (IZTO), indium-gallium-zinc oxide (IGZO), indium-gallium-tin oxide (IGTO), or indium-gallium-zinc-tin oxide (IGZTO), but embodiments are not limited thereto.

The first gate insulating layer 13 may be disposed on the semiconductor layer and the buffer layer 12. The first gate insulating layer 13 may function as a gate insulating film for the driving transistor DT and the switching transistor ST. The first gate insulating layer 13 may be formed as a double layer or a multilayer in which inorganic layers including at least one of SiOₓ, SiNₓ, and SiOₓN_{y} are alternately stacked.

The second conductive layer may be disposed on the first gate insulating layer 13. The second conductive layer may include a first gate electrode DT_G of the driving transistor DT and a second gate electrode ST_G of the switching transistor ST. The first gate electrode DT_G may overlap the first channel region DT_ACTc of the first active material layer DT_ACT in a thickness direction, and the second gate electrode ST_G may overlap the second channel region ST_ACTc of the second active material layer ST_ACT in the thickness direction.

The second conductive layer may be formed as a single layer or a multilayer including one of molybdenum (Mo), aluminum (Al), chromium (Cr), gold (Au), titanium (Ti), nickel (Ni), neodymium (Nd), copper (Cu), and an alloy thereof, but embodiments are not limited thereto.

The first passivation layer 15 may be disposed on the second conductive layer. The first passivation layer 15 may cover and protect the second conductive layer. The first passivation layer 15 may be formed as a double layer or a multilayer in which inorganic layers including at least one of SiOₓ, SiNₓ, and SiOₓN_{y} are alternately stacked.

The third conductive layer may be disposed on the first passivation layer 15. The third conductive layer may include a first capacitance electrode CE1 of a storage capacitor, which overlaps at least partially with the first gate electrode DT_G in the thickness direction. The first capacitance electrode CE1 may overlap the first gate electrode DT_G in the thickness direction with the first passivation layer 15 interposed therebetween, and the storage capacitor may be formed between the first capacitance electrode CE1 and the first gate electrode DT_G. The third conductive layer may be formed as a single layer or a multilayer including one of Mo, Al, Cr, Au, Ti, Ni, Nd, Cu, and an alloy thereof, but embodiments are not limited thereto.

The first interlayer insulating layer 17 may be disposed on the third conductive layer. The first interlayer insulating layer 17 may function as an insulating film between the third conductive layer and layers disposed on the third conductive layer. The first interlayer insulating layer 17 may be formed as a double layer or a multilayer in which inorganic layers including at least one of SiOₓ, SiNₓ, and SiOₓN_{y} are alternately stacked.

The fourth conductive layer may be disposed on the first interlayer insulating layer 17. The fourth conductive layer may include the first source/drain electrode DT_SD1 and a second source/drain electrode DT_SD2 of the driving transistor DT and the first source/drain electrode ST_SD1 and a second source/drain electrode ST_SD2 of the switching transistor ST.

The first source/drain electrode DT_SD1 and the second source/drain electrode DT_SD2 of the driving transistor DT may be in contact with the first and second doped regions DT_ACTa and DT_ACTb of the first active material layer DT_ACT through contact holes penetrating the first interlayer insulating layer 17 and the first gate insulating layer 13. The first source/drain electrode ST_SD1 and the second source/drain electrode ST_SD2 of the switching transistor ST may be in contact with the third and fourth doped regions ST_ACTa and ST_ACTb of the second active material layer ST_ACT through contact holes penetrating the first interlayer insulating layer 17 and the first gate insulating layer 13. The first source/drain electrode DT_SD1 of the driving transistor DT and the first source/drain electrode ST_SD1 of the switching transistor ST may be connected (e.g., electrically connected) to the first and second lower metal layers BML1 and BML2, respectively, through other contact holes. In case that one of the first and second source/drain electrodes DT_SD1 and DT_SD2 of the driving transistor DT or one of the first and second source/drain electrodes ST_SD1 and ST_SD2 of the switching transistor ST is a source electrode, the other source/drain electrode may be a drain electrode, but embodiments are not limited thereto. In another example, in case that one of the first and second source/drain electrodes DT_SD1 and DT_SD2 of the driving transistor DT or one of the first and second source/drain electrodes ST_SD1 and ST_SD2 of the switching transistor ST is a drain electrode, the other source/drain electrode may be a source electrode.

The fourth conductive layer may be formed as a single layer or a multilayer including one of Mo, Al, Cr, Au, Ti, Ni, Nd, Cu, and an alloy thereof, but embodiments are not limited thereto.

The second interlayer insulating layer 18 may be disposed on the fourth conductive layer. The second interlayer insulating layer 18 may be disposed on the entire surface of the first interlayer insulating layer 17, may cover the fourth conductive layer, and may protect the fourth conductive layer. The second interlayer insulating layer 18 may be formed as a double layer or a multilayer in which inorganic layers including at least one of SiOₓ, SiNₓ, and SiOₓN_{y} are alternately stacked.

The fifth conductive layer may be disposed on the second interlayer insulating layer 18. The fifth conductive layer may include a first voltage line VL1, a second voltage line VL2, and the first conductive pattern CDP. A high-potential voltage (or a first power supply voltage), which is to be supplied to the driving transistor DT, may be applied to the first voltage line VL1, and a low-potential voltage (or a second power supply voltage), which is to be supplied to second electrodes 22, may be applied to the second voltage line VL2. An alignment signal for aligning the light-emitting elements 30 may be applied to the second voltage line VL2 during the fabrication of the display device 10.

The first conductive pattern CDP may be connected (e.g., electrically connected) to the first source/drain electrode DT_SD1 of the driving transistor DT through a contact hole formed in the second interlayer insulating layer 18. The first conductive pattern CDP may be in contact with a first electrode 21 that will be described below, and the driving transistor DT may transmit the second power supply voltage from the first voltage line VL1 to the first electrode 21 through the first conductive pattern CDP. The fifth conductive layer is illustrated as including a second voltage line VL2 and a first voltage line VL1, but embodiments are not limited thereto. In another example, the fifth conductive layer may include more than one first voltage line VL1 and more than one second voltage line VL2.

The fifth conductive layer may be formed as a single layer or a multilayer including one of Mo, Al, Cr, Au, Ti, Ni, Nd, Cu, and an alloy thereof, but embodiments are not limited thereto.

The first planarization layer 19 may be disposed on the fifth conductive layer. The first planarization layer 19 may include an organic insulating material, e.g., an organic material such as, for example, polyimide (PI), and may perform a surface planarization function.

First banks 40, electrodes 21 and 22, light-emitting elements 30, a second bank 44, and connecting electrodes 26 and 27 may be disposed on the first planarization layer 19. Insulating layers 51, 52, and 53 may be further disposed on the first planarization layer 19.

The first banks 40 may be disposed (e.g., directly disposed) on the first planarization layer 19. The first banks 40 may extend in the second direction DR2, in each of the subpixels PXn, and may be spaced apart from, and terminated at, the boundary areas between neighboring subpixels PXn in the second direction DR2, not to extend into other subpixels PXn. For example, the first banks 40 may be spaced apart from each other, and may face each other in the first direction DR1. The first banks 40 may be spaced apart from each other to form an area in which to arrange the light-emitting elements 30 therebetween. The first banks 40 may be disposed in each of the subpixels PXn to form linear patterns in the display area DPA of the display device 10. FIG. 3 illustrates three first banks 40, but embodiments are not limited thereto. More than three first banks 40 may be provided according to the number of electrodes 21 and 22 that will be described below.

The first banks 40 may protrude at least in part from the upper surface (e.g., the top surface) of the first planarization layer 19. Each of the protruding parts of the first banks 40 may have inclined sides, and light emitted by the light-emitting elements 30 may travel or transmit toward the inclined sides of each of the first banks 40. The electrodes 21 and 22, which are disposed on the first banks 40, may include a material with high reflectance, and light emitted by the light-emitting elements 30 may be reflected by the electrodes 21 and 22 on sides of the first banks 40 to be emitted in an upward direction of the first planarization layer 19. For example, the first banks 40 may not only provide space in which to arrange the light-emitting elements 30, but also function as reflective partition walls capable of reflecting light emitted by the light-emitting elements 30 in an upward direction. The sides of each of the first banks 40 may be linearly inclined, but embodiments are not limited thereto. In another example, the sides of each of the first banks 40 may have a curved semicircular shape or a semielliptical shape. In an embodiment, the first banks 40 may include an organic insulating material such as polyamide (PI), but embodiments are not limited thereto.

The electrodes 21 and 22 may be disposed on the first banks 40 and the first planarization layer 19. The electrodes 21 and 22 may include the first electrode 21 and the second electrodes 22. The first electrode 21 and the second electrodes 22 may extend in the second direction DR2 and may be spaced apart from each other, and face each other in the first direction DR1. The first electrode 21 and the second electrodes 22 may have a substantially similar shape to the first banks 40 and may be longer than the first banks 40 in the second direction DR2.

The first electrode 21 may extend in the second direction DR2, in each of the subpixels PXn, which forms a pixel area, and may be spaced apart from another first electrode 21 at the boundary area between two adjacent subpixels PXn in the second direction DR2. In some embodiments, the second bank 45 may be disposed along the boundary areas of each of the subpixels PXn, and first electrodes 21 of each pair of adjacent subpixels PXn in the second direction DR2 may be spaced apart from each other by the second bank 45. The first electrode 21 may be connected (e.g., electrically connected) to the driving transistor DT through a first contact hole CT1 disposed in an area surrounded by the second bank 45. For example, at least part of the first electrode 21 may be in contact with the first conductive pattern CDP through the first contact hole CT1, which penetrates the first planarization layer 19. The first electrode 21 may be connected (e.g., electrically connected) to the first source/drain electrode DT_SD1 of the driving transistor DT through the first conductive pattern CDP.

The second electrodes 22 may extend in the second direction DR2 beyond the boundary areas between subpixels PXn that are adjacent to each other in the second direction DR2. In some embodiments, the second electrodes 22 may be disposed in multiple subpixels PXn that are adjacent to each other in the second direction DR2. The second electrodes 22 may partially overlap the second bank 45 at the boundary area between the subpixels PXn that are adjacent to each other in the second direction DR2, and may be connected (e.g., electrically connected) to the second voltage line VL2 through second contact holes CT2. For example, the second electrodes 22 may overlap parts of the second bank 45 that extend in the first direction DR1, and may be in contact with the second voltage line VL2 through the second contact holes CT2, which penetrate the first planarization layer 19. The second power supply voltage may be applied to the second electrodes 22 through the second contact holes CT2. The second electrodes 22 are illustrated as being connected (e.g., electrically connected) to the second voltage line VL2 through second contact holes CT2 disposed at boundary areas of each of the subpixels PXn, but embodiments are not limited thereto. In some embodiments, a single second contact hole CT2 may be disposed in each of the subpixels PXn.

Each of the subpixels PXn is illustrated as including one first electrode 21 and two second electrodes 22, and the first electrode 21 is illustrated as being disposed between the two second electrodes 22. However, embodiments are not limited thereto. In some embodiments, more than one first electrode 21 and more than two second electrodes 22 may be disposed in each of the subpixels PXn. The first electrode 21 and the second electrodes 22, which are disposed in each of the subpixels PXn, may not extend in a direction, but may be arranged in various layouts. For example, the first electrode 21 and the second electrodes 22 may be partially curved or bent, and one of the first electrode 21 and the second electrodes 22 may surround the other electrodes. At least parts of the first electrode 21 and the second electrodes 22 may be spaced apart from each other, and may face each other. For example, the structures and shapes of the first electrode 21 and the second electrodes 22 are not limited thereto, in case that an area in which to arrange the light-emitting elements 30 is formed.

The electrodes 21 and 22 may be connected (e.g., electrically connected) to the light-emitting elements 30, and voltages may be applied to the electrodes 21 and 22 such that the light-emitting elements 30 may emit light. For example, the electrodes 21 and 22 may be connected (e.g., electrically connected) to the light-emitting elements 30, and electrical signals applied to the electrodes 21 and 22 may be transmitted to the light-emitting elements 30 through the connecting electrodes 26 and 27.

The electrodes 21 and 22 may be used to generate an electric field in each of the subpixels PXn to align the light-emitting elements 30. The light-emitting elements 30 may be disposed between the first electrode 21 and the second electrodes 22 by an electric field formed on the first electrode 21 and the second electrodes 22. As will be described below, the light-emitting elements 30 may be sprayed onto the first electrode 21 and the second electrodes 22 in a state of being dispersed in ink by an inkjet printing process and may be aligned between the first and second electrodes 21 and 22 by applying alignment signals between the first electrode 21 and the second electrodes 22.

As illustrated in FIG. 3, the first electrode 21 and the second electrodes 22 may be disposed on the first banks 40. The first electrode 21 and the second electrodes 22 may be spaced apart from each other, and may face each other in the first direction DR1. For example, light-emitting elements 30 may be disposed between the first electrode 21 and the second electrodes 22. The light-emitting elements 30 may be disposed between the first electrode 21 and the second electrodes 22, and at the same time, connected (e.g., electrically connected) to the first electrode 21 and the second electrodes 22.

In some embodiments, the first electrode 21 and the second electrodes 22 may have a larger width than the first banks 40. For example, the first electrode 21 and the second electrodes 22 may cover the outer surfaces of the first banks 40. The first electrode 21 and the second electrodes 22 may be disposed on sides of the first banks 40, and the distance between the first electrode 21 and the second electrodes 22 may be less than the distance between the first banks 40. For example, at least parts of first electrode 21 and the second electrodes 22 may be disposed (e.g., directly disposed) on the first planarization layer 19.

The electrodes 21 and 22 may include a transparent conductive material. For example, the electrodes 21 and 22 may include a material such as ITO, IZO, or ITZO, but embodiments are not limited thereto. In some embodiments, the electrodes 21 and 22 may include a conductive material with high reflectance. For example, the electrodes 21 and 22 may include a material with high reflectance such as silver (Ag), copper (Cu), or Al. In this example, the electrodes 21 and 22 may reflect light emitted by the light-emitting elements 30 to travel or transmit toward sides of the first banks 40, in an upward direction of each of the subpixels PXn.

However, embodiments are not limited thereto. In another example, the electrodes 21 and 22 may have a stack of one or more layers of a transparent conductive material and one or more layers of a metal with high reflectance or may be formed as a single layer including the transparent conductive material and the metal with high reflectance. In an embodiment, the electrodes 21 and 22 may have a stack of ITO/Ag/ITO, ITO/Ag/IZO, or ITO/Ag/ITZO/IZO or may include an alloy of Al, Ni, or lanthanum (La). In another example, the electrodes 21 and 22 may have a structure in which a layer of a metal such as Ti or Mo and an alloy of Al, Ni, or La are stacked. In some embodiments, the electrodes 21 and 22 may be formed as double layers or multilayers in which an alloy of Al and at least one layer of Ti or Mo are stacked.

The first insulating layer 51 may be disposed on the first planarization layer 19, the first electrode 21, and the second electrodes 22. The first insulating layer 51 may cover not only the first electrode 21 and the second electrodes 22, but also the gaps between the first electrode 21 and the second electrodes 22. For example, the first insulating layer 51 may cover most of the upper surfaces (e.g., the top surfaces) of the first electrode 21 and the second electrodes 22, but may expose parts of the first electrode 21 and the second electrodes 22. The first insulating layer 51 may expose parts of the upper surfaces of the first electrode 21 and the second electrodes 22 on, for example, the first banks 40. The first insulating layer 51 may be formed on substantially the entire surface of the first planarization layer 19 and may include openings, which partially expose the first electrode 21 and the second electrodes 22.

In an embodiment, the first insulating layer 51 may be stepped such that parts of the upper surface (e.g., the top surface) of the first insulating layer 51 may be recessed between the first electrode 21 and the second electrodes 22. In some embodiments, the first insulating layer 51 may include an inorganic insulating material, and part of the upper surface of the first insulating layer 51, which covers the first electrode 21 and the second electrodes 22, may be recessed due to the height differences formed by the underlying elements. The light-emitting elements 30, which are disposed on the first insulating layer 51, between the first electrode 21 and the second electrodes 22, may form empty spaces with the recessed part of the upper surface of the first insulating layer 51. The light-emitting elements 30 may be spaced apart from the upper surface of the first insulating layer 51, and the spaces between the first insulating layer 51 and the light-emitting elements 30 may be filled with the material of the connecting electrodes 26 and 27 that will be described below. However, embodiments are not limited thereto. The first insulating layer 51 may form a flat surface on which to arrange the light-emitting elements 30.

The first insulating layer 51 may protect the first electrode 21 and the second electrodes 22 and may insulate the first electrode 21 and the second electrodes 22 from each other. For example, the first insulating layer 51 may prevent the light-emitting elements 30, which are disposed on the first insulating layer 51, from being in direct contact with, and damaged by, other elements. However, the shape and structure of the first insulating layer 51 are not limited thereto.

The second bank 45 may be disposed on the first insulating layer 51. In some embodiments, the second bank 45 may surround not only the region where the first banks 40 are disposed, but also the region where the light-emitting elements 30 are disposed, on the first insulating layer 51 and may be arranged along the boundary areas between the subpixels PXn. The second bank 45 may extend in the first and second directions DR1 and DR2 and may thus form a lattice pattern on the entire surface of the display area DPA. Parts of the second bank 45 that extend in the first direction DR1 may overlap in part with the first electrode 21 and the second electrodes 22, and parts of the second bank 45 that extend in the second direction DR2 may be spaced apart from the first banks 40, the first electrode 21, and the second electrodes 22.

The height of the second bank 45 may be greater than the height of the first banks 40. The second bank 45 may define neighboring subpixels PXn and may prevent ink from spilling (or overflowing) over between the neighboring subpixels PXn during an inkjet printing process for aligning the light-emitting elements 30 during the fabrication of the display device 10. The second bank 45 may separate ink having different sets of light-emitting elements 30 not to be mixed together. The second bank 45, like the first banks 40, may include polyimide (PI), but embodiments are not limited thereto.

The light-emitting elements 30 may be disposed between the electrodes 21 and 22. In an embodiment, the light-emitting elements 30 may extend in a direction and may be spaced apart from each other and aligned substantially in parallel to each other. The distance between the light-emitting elements 30 is not limited thereto. Some of the light-emitting elements 30 may be disposed adjacent to each other to form a group, and some of the light-emitting elements 30 may be spaced apart from each other by a distance to form another group. In another example, the light-emitting elements 30 may be arranged to have a nonuniform density. For example, the direction in which the electrodes 21 and 22 extend may form a substantially right angle with the direction in which the light-emitting elements 30 extend. However, embodiments are not limited thereto. In another example, the light-emitting elements 30 may extend diagonally with respect to the direction in which the electrodes 21 and 22 extend.

The light-emitting elements 30 may include active layers (“36” of FIG. 6) including different materials and may thus emit light of different wavelength bands to the outside. The display device 10 may include light-emitting elements 30 capable of emitting light of different wavelength bands. For example, the light-emitting elements 30 of the first subpixel PX1 may include active layers 36 emitting first-color light having a first wavelength as a central wavelength, the light-emitting elements 30 of the second subpixel PX2 may include active layers 36 emitting second-color light having a second wavelength as a central wavelength, and the light-emitting elements 30 of the third subpixel PX3 may include active layers 36 emitting third-color light having a third wavelength as a central wavelength.

Accordingly, the first, second, and third subpixels PX1, PX2, and PX3 may emit the first-color light, the second-color light, and the third-color light, respectively. In some embodiments, the first-color light may be blue light having a central wavelength of about 450 nm to about 495 nm, the second-color light may be green light having a central wavelength of about 495 nm to about 570 nm, and the third-color light may be red light having a central wavelength of about 620 nm to about 752 nm. However, embodiments are not limited thereto. In another example, the first, second, and third subpixels PX1, PX2, and PX3 may include light-emitting elements 30 of the same type and may thus emit light of the same color.

The light-emitting elements 30 may be disposed on the first insulating layer 51, between the first banks 40 or between the electrodes 21 and 22. For example, at least one end portion of each of the light-emitting elements 30 may be disposed on the first or second electrode 21 or 22. The length of the light-emitting elements 30 may be greater than the distance between the first electrode 21 and the second electrodes 22, and end portions (e.g., opposite end portions) of each of the light-emitting elements 30 may be disposed on the first electrode 21 and the second electrodes 22. However, embodiments are not limited thereto. In another example, a single end portion of each of the light-emitting elements 30 may be disposed on the electrodes 21 and 22, or end portions (e.g., opposite end portions) of each of the light-emitting elements 30 may not be disposed on the electrodes 21 and 22. In case that the light-emitting elements 30 are not disposed on the electrodes 21 and 22, end portions (e.g., opposite end portions) of each of the light-emitting elements 30 may be connected (e.g., electrically connected) to the electrodes 21 and 22 through the connecting electrodes 26 and 27 that will be described below. In some embodiments, at least parts of the light-emitting elements 30 may be disposed between the first electrode 21 and the second electrodes 22, and end portions (e.g., opposite end portions) of each of the light-emitting elements 30 may be connected (e.g., electrically connected) to the electrodes 21 and 22.

In each of the light-emitting elements 30, layers may be arranged in a direction perpendicular to the upper surface (e.g., the top surface) of the first substrate 11 or the first planarization layer 19. The light-emitting elements 30 may extend in a direction and may have a structure in which semiconductor layers are sequentially arranged. The light-emitting elements 30 may be disposed such that the direction in which the light-emitting elements 30 of the display device 10 extend may be parallel to the first planarization layer 19, and the semiconductor layers included in each of the light-emitting elements 30 may be sequentially arranged in a direction parallel to the upper surface of the first planarization layer 19. However, embodiments are not limited thereto. In a case where the light-emitting elements 30 may have a different structure, the layers of each of the light-emitting elements 30 may be arranged in a direction perpendicular to the first planarization layer 19.

For example, end portions (e.g., opposite end portions) of each of the light-emitting elements 30 may be in contact with the connecting electrodes 26 and 27. As an insulating film (“38” of FIG. 6) is not formed, but some of the semiconductor layers of each of the light-emitting elements 30 are exposed on end surfaces (e.g., opposite end surfaces), in the extension direction, of each of the light-emitting elements 30, the exposed semiconductor layers may be in contact with the connecting electrodes 26 and 27, but embodiments are not limited thereto. At least part of the insulating film 38 of each of the light-emitting elements 30 may be removed, and sides of the semiconductor layers of each of the light-emitting elements 30 may be partially exposed. The exposed sides of the semiconductor layers of each of the light-emitting elements 30 may be in direct contact with the connecting electrodes 26 and 27.

During the fabrication of the display device 10, the light-emitting elements 30, which are dispersed in ink, may be sprayed into each of the subpixels PXn. In case that the ink is sprayed, alignment signals may be applied to the electrodes 21 and 22 to generate an electric field in the ink. As the light-emitting elements 30 receive a force from the electric field, the orientation directions and positions of the light-emitting elements 30 may continue to change. Thus, the light-emitting elements 30 may be disposed on the electrodes 21 and 22. The light-emitting elements 30 may be aligned between the electrodes 21 and 22 such that the direction, in which the light-emitting elements 30 extend, may face a certain direction. For example, the ink is sprayed into each region defined by the second bank 45, which is disposed along the boundary areas of each of the subpixels PXn. As the light-emitting elements 30 are randomly dispersed in the ink, at least some of the light-emitting elements 30 may be disposed in regions other than regions between the electrodes 21 and 22, even in the presence of the electric field. These light-emitting elements 30 may not be electrically connected to the electrodes 21 and 22, and may become lost during the fabrication of the display device 10.

The display device 10 may include an alignment-inducing layer 70, which guides the light-emitting elements 30 to be seated at a certain location in case that the ink having the light-emitting elements 30 dispersed therein is sprayed into each of the subpixels PXn during the fabrication of the display device 10. The ink sprayed into each of the subpixels PXn may settle in (or move to) a certain region formed by the alignment-inducing layer 70. Thus, the light-emitting elements 30 may be densely arranged in the certain region. As the display device 10 includes the alignment-inducing layer 70, the loss amounts of the light-emitting elements 30 during the fabrication of the display device 10 may be minimized, and the light-emitting elements 30 may be densely disposed at a certain location.

The alignment-inducing layer 70 may include a hydrophobic material. The polarity of the material of the alignment-inducing layer 70 may vary according to the chemical polarity of the solvent of the ink. In an embodiment, the solvent of ink having the light-emitting elements 30 dispersed therein, during the fabrication of the display device 10, may be a hydrophilic solvent, and the alignment-inducing layer 70 may include a hydrophobic material and may thus guide the ink to settle in (or move to) a region where the alignment-inducing layer 70 is not disposed. The ink containing the hydrophilic solvent may be densely seated at locations, in each of the subpixels PXn, where the alignment-inducing layer 70 is not disposed, and the light-emitting elements 30 may be disposed not to overlap parts of the alignment-inducing layer 70 that include the hydrophobic material. However, embodiments are not limited thereto. In another example, the alignment-inducing layer 70 may include parts that include a hydrophilic material, like the solvent of the ink. This will be described below with embodiments.

The alignment-inducing layer 70 may be disposed in each of the subpixels PXn. The location of the alignment-inducing layer 70 may vary according to the region where the light-emitting elements 30 are disposed. In an embodiment, the alignment-inducing layer 70 may surround at least parts of the regions between the electrodes 21 and 22 in each of the subpixels PXn. For example, the alignment-inducing layer 70 may surround the space where the electrodes 21 and 22 are spaced apart from each other in each of the subpixels PXn. The alignment-inducing layer 70 may include first extensions 70A, which extend in the first direction DR1, and second extensions 70B, which extend in the second direction DR2. The first extensions 70A of the alignment-inducing layer 70 may intersect the electrodes 21 and 22 and may thus overlap parts of the electrodes 21 and 22. The first extensions 70A may extend across the electrodes 21 and 22, in areas that do not overlap the first bank 40 in each of the subpixels PXn, e.g., in the upper and lower parts of each of the subpixels PXn. The second extensions 70B of the alignment-inducing layer 70 may be disposed between outermost electrodes OE, which are disposed on the outermost sides from the center area of each of the subpixels PXn, and the parts of the second bank 45 that extend in the second direction DR2. Accordingly, the alignment-inducing layer 70 may surround the regions between the electrodes 21 and 22 or the first banks 40, in a plan view.

In a case where the alignment-inducing layer 70 includes a hydrophobic material, the light-emitting elements 30 may be densely arranged in the region where the alignment-inducing layer 70 is not disposed. As described above, each of the subpixels PXn may include an emission area EMA where the light-emitting elements 30 emit light. For example, each of the subpixels PXn may include an alignment area AA, in which the light-emitting elements 30 are densely arranged due to the presence of the alignment-inducing layer 70, and a non-alignment area NAA where the distribution of the light-emitting elements 30 is relatively low. For example, the display device 10 may include the emission area EMA in each of the subpixels PXn, and the emission area EMA may include the alignment area AA, in which the light-emitting elements 30 are densely arranged, and the non-alignment area NAA, which is the entire emission area EMA except for the alignment area AA. As not only the alignment area AA, but also the non-alignment area NAA is reached by light emitted from the light-emitting elements 30 in the alignment area AA, the alignment area AA and the non-alignment area NAA may be included in the emission area EMA.

The alignment area AA and the non-alignment area NAA may be classified according to the number, distribution, or density of light-emitting elements 30 disposed per unit area, and the shapes and locations of the alignment area AA and the non-alignment area NAA may be related to the layout of the alignment-inducing layer 70. For example, the non-alignment area NAA may be adjacent to the alignment area AA and may partially or entirely surround the alignment area AA. For example, in a case where the alignment-inducing layer 70 only includes a hydrophobic material, the light-emitting elements 30 may be densely arranged only in the region where the alignment-inducing layer 70 is not disposed, in which case, the region where the alignment-inducing layer 70 is disposed and the region where not the alignment-inducing layer 70, but the light-emitting elements 30 are disposed may be the non-alignment area NAA and the alignment area AA, respectively.

However, embodiments are not limited thereto. In another example, the alignment-inducing layer 70 may further include a hydrophilic material, and at least part of the region where the alignment-inducing layer 70 is disposed may be the alignment area AA. The display device 10 may include the alignment area AA and the non-alignment area NAA in each of the subpixels PXn, and at least part of the alignment-inducing layer 70 may be disposed in the non-alignment area NAA. Part of the alignment-inducing layer 70 that includes a hydrophobic material may be disposed in the non-alignment area NAA to surround the alignment area AA, and the light-emitting elements 30 may be densely arranged in the alignment area AA.

The alignment-inducing layer 70 may be disposed on the first insulating layer 51. The alignment-inducing layer 70 may be disposed in regions other than the region where the light-emitting elements 30 are disposed, on the first insulating layer 51, which partially covers the electrodes 21 and 22. For example, the alignment-inducing layer 70 may be disposed on the first insulating layer 51, in the non-alignment area NAA.

In each of the subpixels PXn, only one alignment area AA may be provided by the alignment-inducing layer 70, but embodiments are not limited thereto. As already mentioned above, the locations or shapes of the alignment area AA and the non-alignment area NAA may vary according to the layout of the alignment-inducing layer 70. In some embodiments, the alignment-inducing layer 70 may separate the subpixels PXn, and each of the subpixels PXn may include multiple alignment areas AA.

The second insulating layer 52 may be disposed in part on the light-emitting elements 30, which are disposed between the first electrode 21 and the second electrodes 22. The second insulating layer 52 may surround parts of the outer surfaces of each of the light-emitting elements 30. Parts of the second insulating layer 52 on the light-emitting elements 30 may extend in the second direction DR2 between the first electrode 21 and the second electrodes 22. For example, the second insulating layer 52 may form linear patterns or island patterns in each of the subpixels PXn.

The second insulating layer 52 may be disposed on the light-emitting elements 30 to expose first end portions and second end portions of the light-emitting elements 30. The exposed end portions of each of the light-emitting elements 30 may be in contact with the connecting electrodes 26 and 27. The second insulating layer 52 may be formed by a typical mask process through patterning. A mask for forming the second insulating layer 52 may have a smaller width than the length of the light-emitting elements 30, and the second insulating layer 52 may be patterned to expose end portions (e.g., opposite end portions) of each of the light-emitting elements 30. However, embodiments are not limited thereto.

The second insulating layer 52 may protect and fix the light-emitting elements 30 during the fabrication of the display device 10. In an embodiment, some of the material of the second insulating layer 52 may be disposed between the lower surfaces (e.g., the bottom surfaces) of the light-emitting elements 30 and the first insulating layer 51. As already mentioned above, the second insulating layer 52 may fill the spaces between the first insulating layer 51 and the light-emitting elements 30 during the fabrication of the display device 10. Accordingly, the second insulating layer 52 may surround the outer surfaces of each of the light-emitting elements 30 and may protect and fix the light-emitting elements 30 during the fabrication of the display device 10.

The connecting electrodes 26 and 27 may be disposed on the first electrode 21 and the second electrodes 22. The connecting electrodes 26 and 27 may include first connecting electrodes 26, which are disposed on the first electrode 21 and are in contact with the first end portions of the light-emitting elements 30, and second connecting electrodes 27, which are disposed on the second electrodes 22 and are in contact with the second end portions of the light-emitting elements 30.

The first connecting electrodes 26 and the second connecting electrodes 27 may extend in the second direction DR2 in each of the subpixels PXn to be spaced apart from each other, and may face each other in the first direction DR1. The first connecting electrodes 26 and the second connecting electrodes 27 may be spaced apart from each other, and may face each other in the region where the light-emitting elements 30 are disposed, for example, between the first electrode 21 and the second electrodes 22. In some embodiments, the connecting electrodes 26 and 27 may form linear patterns in each of the subpixels PXn.

The first connecting electrodes 26 and the second connecting electrodes 27 may be in contact with parts of the upper surfaces of the first electrode 21 and the second electrodes 22 that are exposed due to the absence of the first insulating layer 51. For example, the connecting electrodes 26 and 27 may be in contact with the first end portions of the light-emitting elements 30. In some embodiments, the connecting electrodes 26 and 27 may include a conductive material, and the light-emitting elements 30 may be connected (e.g., electrically connected) to the electrodes 21 and 22 by being in contact with the connecting electrodes 26 and 27. As already mentioned above, some of the semiconductor layers of each of the light-emitting elements 30 may be exposed at end portions (e.g., opposite end portions) of each of the light-emitting elements 30, and the connecting electrodes 26 and 27 may be in contact with (e.g., in direct contact with) the exposed semiconductor layers of each of the light-emitting elements 30. The first connecting electrodes 26 and the second connecting electrodes 27 may extend in the second direction DR2 and may surround parts of the outer surfaces of each of the light-emitting elements 30, which are disposed between the electrodes 21 and 22.

In an embodiment, the width of the connecting electrodes 26 and 27 may be less than the width of the electrodes 21 and 22. The connecting electrodes 26 and 27 may be in contact with the first end portions of the light-emitting elements 30 and may cover sides of the electrodes 21 and 22. The first connecting electrodes 26 may be disposed on the first electrode 21 to be spaced apart from each other and cover sides (e.g., opposite sides) of the first electrode 21, in a plan view. The second connecting electrodes 27 may cover sides of the second electrodes 22 that face the first electrode 21. The first connecting electrodes 26 and the second connecting electrodes 27 may be in contact with parts of the upper surfaces of the first electrode 21 and the second electrodes 22 and may be in contact with the first end portions of the light-emitting elements 30.

Each of the subpixels PXn is illustrated as including two first connecting electrodes 26 and two second connecting electrodes 27, but embodiments are not limited thereto. The numbers of first connecting electrodes 26 and second connecting electrodes 27 may vary according to the numbers of first electrodes 21 and second electrodes 22 in each of the subpixels PXn.

The connecting electrodes 26 and 27 may include a conductive material. For example, the connecting electrodes 26 and 27 may include ITO, IZO, ITZO, or Al. For example, the connecting electrodes 26 and 27 may include a transparent conductive material, and light emitted by the light-emitting elements 30 may travel or transmit toward the electrodes 21 and 22 through the connecting electrodes 26 and 27. The electrodes 21 and 22, which are disposed on inclined sides of the first banks 40, may include a material with high reflectance and may reflect incident light in an upward direction from the first substrate 11, but embodiments are not limited thereto.

The third insulating layer 53 may be disposed on the first connecting electrode 26. The third insulating layer 53 may electrically insulate the first connecting electrodes 26 and the second connecting electrodes 27. The third insulating layer 53 may cover the first connecting electrodes 26, but may not be disposed on the second end portions of the light-emitting elements 30 such that the light-emitting elements 30 may be in contact with the second connecting electrodes 27. The third insulating layer 53 may be in partial contact with the first connecting electrodes 26 and the second connecting electrodes 27, on the upper surface (e.g., the top surface) of the second insulating layer 52. Sides of the third insulating layer 53 where the second electrodes 22 are disposed may be aligned with sides of the second insulating layer 52, but embodiments are not limited thereto. Accordingly, the second connecting electrodes 27 may be disposed on the second electrodes 22, the second insulating layer 52, and the third insulating layer 53. The first connecting electrodes 26 may be disposed between the first electrode 21 and the third insulating layer 53, and the second connecting electrodes 27 may be disposed on the third insulating layer 53. The first connecting electrodes 26 and the second connecting electrodes 27 may not be in contact with each other due to the second and third insulating layers 52 and 53, but embodiments are not limited thereto. In another example, the third insulating layer 53 may be omitted.

The fourth insulating layer 54 may be disposed on the entire surface of the first substrate 11. The fourth insulating layer 54 may protect the elements disposed on the first substrate 11 from an external environment.

The first, second, third, and fourth insulating layers 51, 52, 53, and 54 may include an inorganic insulating material or an organic insulating material. In an embodiment, the first, second, third, and fourth insulating layers 51, 52, 53, and 54 may include an inorganic insulating material such as SiOₓ, SiNₓ, SiOₓN_{y}, Al₂O₃, or AlN. In another example, the first, second, third, and fourth insulating layers 51, 52, 53, and 54 may include an organic insulating material such as an acrylic resin, an epoxy resin, a phenolic resin, a polyamide resin, a polyimide resin, an unsaturated polyester resin, a polyphenylene resin, a polyphenylene sulfide resin, benzocyclobutene, a cardo resin, a siloxane resin, a silsesquioxane resin, polymethyl methacrylate, polycarbonate, or a polymethyl methacrylate-polycarbonate synthetic resin, but embodiments are not limited thereto.

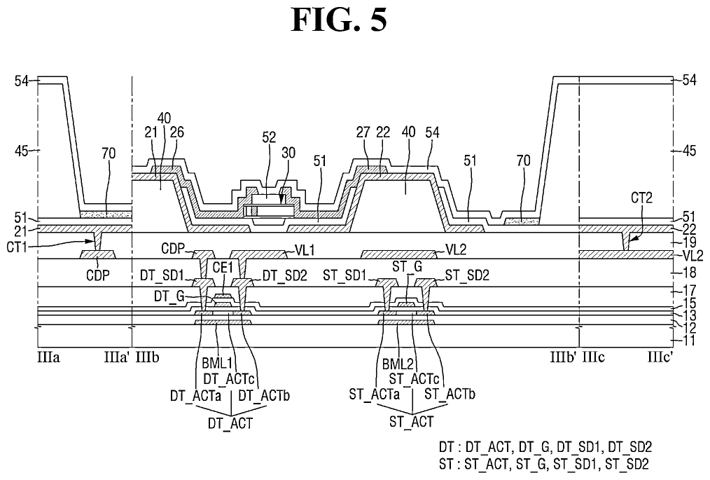

FIG. 5 is a partial schematic cross-sectional view of a display device 10 according to an embodiment.

Referring to FIG. 5, a display device 10 may not include a third insulating layer 53. Parts of second connecting electrodes 27 may be disposed (e.g., directly disposed) on a second insulating layer 52. First connecting electrodes 26 and the second connecting electrodes 27 may be spaced apart from each other on the second insulating layer 52. Even though a third insulating layer 53 is not provided, the second insulating layer 52 may include an organic insulating material and may thus be able to perform the function of fixing light-emitting elements 30. The first connecting electrodes 26 and the second connecting electrodes 27 may be formed at the same time by patterning. The embodiment of FIG. 5 is the same as the embodiment of FIG. 3 except that a third insulating layer 53 is not provided.

The display device 10 may include, in each subpixel PXn, an alignment-inducing layer 70 and may thus have an alignment area AA where the light-emitting elements 30 are densely arranged. During the fabrication of the display device 10, ink having the light-emitting elements 30 dispersed therein may settle in (or move to) a region where the alignment-inducing layer 70 is not disposed, in case that the ink is sprayed into each region surrounded by a second bank 45. The light-emitting elements 30, which are disposed between electrodes 21 and 22, may be densely arranged in the alignment area AA formed by the alignment-inducing layer 70. The display device 10 may reduce the waste of light-emitting elements 30 and may precisely locate the light-emitting elements 30 at targeted locations in each subpixel PXn.

The light-emitting elements 30 may be LEDs, e.g., inorganic LEDs having a size of several micro- or nano-meters and formed of an inorganic material. The inorganic LEDs may be aligned between two opposing electrodes where polarity is formed in response to an electric field being generated in a certain direction therebetween.

FIG. 6 is a schematic view of a light-emitting element 30 according to an embodiment.

Referring to FIG. 6, a light-emitting element 30 may extend in a direction. The light-emitting element 30 may have a rod, wire, or tube shape. In an embodiment, the light-emitting element 30 may have a cylindrical or rod shape. However, the shape of the light-emitting element 30 is not limited thereto, and the light-emitting element 30 may have various shapes such as a polygonal prism shape, for example, a cube shape, a rectangular parallelepiped shape, or a hexagonal prism shape, or a shape extending in a direction with parts of the outer surfaces thereof inclined.

The light-emitting element 30 may include semiconductor layers doped with impurities of an arbitrary conductivity type (e.g., a p type or an n type). The semiconductor layers may receive electrical signals applied thereto from an external source and may thereby emit light of a certain wavelength band. The semiconductor layers included in the light-emitting element 30 may be sequentially arranged or stacked in a direction.

The light-emitting element 30 may include a first semiconductor layer 31, a second semiconductor layer 32, an active layer 36, an electrode layer 37, and an insulating film 38. To properly visualize the elements of the light-emitting element 30, FIG. 6 illustrates a light-emitting element 30 with part of the insulating film 38 removed to expose semiconductor layers 31, 32, and 36. However, as will be described below, the insulating film 38 may surround the outer surfaces of the semiconductor layers 31, 32, and 36.

Specifically, the first semiconductor layer 31 may be an n-type semiconductor. For example, in a case where the light-emitting element 30 emits blue-wavelength light, the first semiconductor layer 31 may include a semiconductor material, e.g., AlₓGa_{y}In_{1-x-y}N (where 0≤x≤1, 0≤y≤1, and 0≤x+y≤1). For example, the first semiconductor layer 31 may include at least one of AlGaInN, GaN, AlGaN, InGaN, AlN, and InN that are doped with an n-type dopant. The first semiconductor layer 31 may be doped with an n-type dopant, and the n-type dopant may be, for example, Si, Ge, or Sn. For example, the first semiconductor layer 31 may be n-GaN doped with Si as an n-type dopant. The first semiconductor layer 31 may have a length of about 1.5 μm to about 5 μm, but embodiments are not limited thereto.

The second semiconductor layer 32 may be disposed on the active layer 36 that will be described below. The second semiconductor layer 32 may be a p-type semiconductor. In a case where the light-emitting element 30 emits blue- or green-wavelength light, the second semiconductor layer 32 may include a semiconductor material, e.g., AlₓGa_{y}In_{1-x-y}N (where 0≤x≤1, 0≤y≤1, and 0≤x+y≤1). For example, the second semiconductor layer 32 may include at least one of AlGaInN, GaN, AlGaN, InGaN, AlN, and InN that are doped with a p-type dopant. The second semiconductor layer 32 may be doped with a p-type dopant, and the p-type dopant may be, for example, Mg, Zn, Ca, Se, or Ba. In an embodiment, the second semiconductor layer 32 may be p-GaN doped with Mg as a p-type dopant. The second semiconductor layer 32 may have a length of about 0.05 μm to about 0.10 μm, but embodiments are not limited thereto.

The first and second semiconductor layers 31 and 32 are illustrated as being formed as single layers, but embodiments are not limited thereto. In some embodiments, each of the first and second semiconductor layers 31 and 32 may include more than one layer such as, for example, a clad layer or a tensile strain barrier reducing (TSBR) layer, according to the material of the active layer 36.

The active layer 36 may be disposed between the first and second semiconductor layers 31 and 32. The active layer 36 may include a single-quantum well structure material or a multi-quantum well structure material. In a case where the active layer 36 includes a material having a multi-quantum well structure, the active layer 36 may have a structure in which multiple quantum layers and multiple well layers are alternately stacked. The active layer 36 may emit light by combining electron-hole pairs in accordance with electrical signals applied thereto via the first and second semiconductor layers 31 and 32. For example, in a case where the active layer 36 emits blue-wavelength light, the quantum layers may include a material such as AlGaN or AlGaInN. In a case where the active layer 36 has a multi-quantum well structure in which multiple quantum layers and multiple well layers are alternately stacked, the quantum layers may include a material such as AlGaN or AlGaInN, and the well layers may include a material such as GaN or AlInN. In an embodiment, in a case where the active layer 36 includes AlGaInN as its quantum layer(s) and AlInN as its well layer(s), the active layer 36 may emit blue light having a central wavelength band of about 450 nm to about 495 nm.

However, embodiments are not limited thereto. In another example, the active layer 36 may have a structure in which a semiconductor material having a large band gap energy and a semiconductor material having a small band gap energy are alternately stacked or may include group-III or group-V semiconductor materials according to the wavelength of light to be emitted. The type of light emitted by the active layer 36 is not limited thereto. The active layer 36 may emit light of a red or green wavelength band, instead of blue light. The active layer 36 may have a length of about 0.05 μm to about 0.10 μm, but embodiments are not limited thereto.

Light may be emitted not only from the circumferential surface, in a lengthwise direction, of the light-emitting element 30, but also from sides (e.g., opposite sides) of the light-emitting element 30. The direction in which light is emitted from the active layer 36 is not limited thereto.

The electrode layer 37 may be an ohmic connecting electrode, but embodiments are not limited thereto. In another example, the electrode layer 37 may be a Schottky connecting electrode. The light-emitting element 30 may include at least one electrode layer 37. The light-emitting element 30 is illustrated as including one electrode layer 37, but embodiments are not limited thereto. In another example, the light-emitting element 30 may include more than one electrode layer 37, or the electrode layer 37 may be omitted. However, the following description of the light-emitting element 30 may also be applicable to a light-emitting element 30 having more than one electrode layer 37 or having a different structure from the light-emitting element 30 of FIG. 6.

The electrode layer 37 may reduce the resistance between the light-emitting element 30 and an electrode (or a connecting electrode) in case that the light-emitting element 30 is connected (e.g., electrically connected) to the electrode (or the connecting electrode) in the display device 10. The electrode layer 37 may include a conductive metal. For example, the electrode layer 37 may include at least one of Al, Ti, In, Au, Ag, ITO, IZO, and ITZO. For example, the electrode layer 37 may include a semiconductor material doped with an n-type dopant or a p-type dopant. The electrode layer 37 may have a length of about 0.05 μm to about 0.10 μm, but embodiments are not limited thereto.

The insulating film 38 may surround the outer surfaces of the above-described semiconductor layers and the above-described electrode layer. In an embodiment, the insulating film 38 may surround at least the outer surface of the active layer 36 and may extend in the direction in which the light-emitting element 30 extends. The insulating film 38 may protect other elements of the light-emitting element 30. For example, the insulating film 38 may surround the sides of the other elements of the light-emitting element 30, but expose end portions (e.g., opposite end portions), in the lengthwise direction, of the light-emitting element 30.

The insulating film 38 is illustrated as extending in the lengthwise direction of the light-emitting element 30 to cover sides of the layers of the light-emitting element 30, ranging from the first semiconductor layer 31 to the electrode layer 37, but embodiments are not limited thereto. The insulating film 38 may cover the outer surfaces of only some of the semiconductor layers, including the active layer 36, or may cover only part of the outer surface of the electrode layer 37 to expose part of the outer surface of the electrode layer 37. For example, the insulating film 38 may have a round upper surface (e.g., a round top surface) near at least one end portion of the light-emitting element 30.

The insulating film 38 may have a thickness of about 10 nm to about 1.0 μm, but embodiments are not limited thereto. For example, the insulating film 38 may have a thickness of about 40 nm.

The insulating film 38 may include a material with insulating properties such as, for example, SiOₓ, SiNₓ, SiOₓN_{y}, AlNₓ, or AlOₓ. The insulating film 38 may prevent any short circuit that may occur in case that the active layer 36 is disposed in direct contact with electrodes that transmit electrical signals directly to the light-emitting element 30. For example, since the insulating film 38 includes the active layer 36 to protect the outer surface of the light-emitting element 30, any degradation in the emission efficiency of the light-emitting element 30 may be prevented.

In some embodiments, the outer surface of the insulating film 38 may be subjected to surface treatment. The light-emitting element 30, which is dispersed in ink, may be sprayed on electrodes during the fabrication of the display device 10. For example, the surface of the insulating film 38 may be hydrophobically or hydrophilically treated to keep the light-emitting element 30 scattered in ink without agglomerating with other light-emitting elements 30.

A length h of the light-emitting element 30 may be in the range of about 1 μm to about 10 μm, in the range of about 2 μm to about 6 μm, or in the range of about 3 μm to about 5 μm. For example, the diameter of the light-emitting element 30 may be in the range of about 30 nm to about 700 nm, and the aspect ratio of the light-emitting element 30 may be about 1.2 to about 100. However, embodiments are not limited thereto. Light emitting elements 30 included in the display device 10 may have different diameters according to the composition of their respective active layers 36. For example, the diameter of the light-emitting element 30 may be about 500 nm.

A method of manufacturing the display device 10 will hereinafter be described.

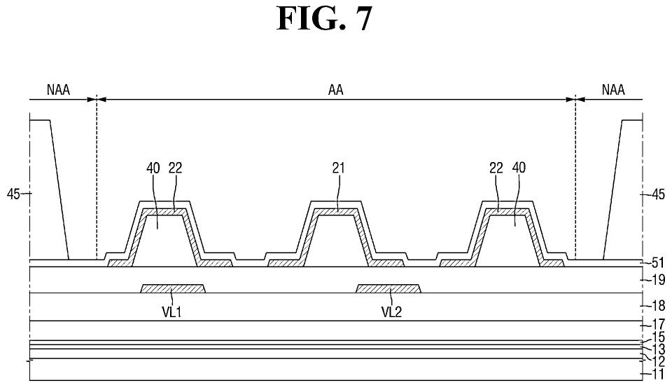

FIGS. 7 through 12 are schematic cross-sectional views illustrating the method of manufacturing a display device 10 according to an embodiment.

Referring to FIG. 7, the target substrate SUB is prepared, and the electrodes 21 and 22 are formed on the target substrate SUB. The electrodes 21 and 22 may include a first electrode 21 and second electrodes 22, which are spaced apart from each other, and face the first electrode 21. For example, first banks 40 may be further disposed between the first electrode 21 and the second electrodes 22 and the target substrate SUB. For example, the target substrate SUB may include a first substrate 11 and circuit elements, which are formed by conductive layers and insulating layers. For descriptive convenience, the first substrate 11 and the circuit elements are simply illustrated and described as the target substrate SUB.

Thereafter, a first insulating layer 51 and a second bank 45, which is disposed on the first insulating layer 51, are formed on the electrodes 21 and 22. The electrodes 21 and 22, the first insulating layer 51, the first banks 40, and the second bank 45 may be formed by a typical deposition process or a mask process. The first insulating layer 51 may cover all the electrodes 21 and 22 and may be partially removed later before the formation of connecting electrodes 26 and 27. The first insulating layer 51 may be patterned later to expose the upper surfaces of the electrodes 21 and 22 and may thus have the structure illustrated in FIG. 3. The layout and the structure of the first insulating layer 51 are as already described above. A description of how to form each element of a display device 10 will be omitted, and instead, the order in which the elements of the display device 10 are formed will be described in detail.

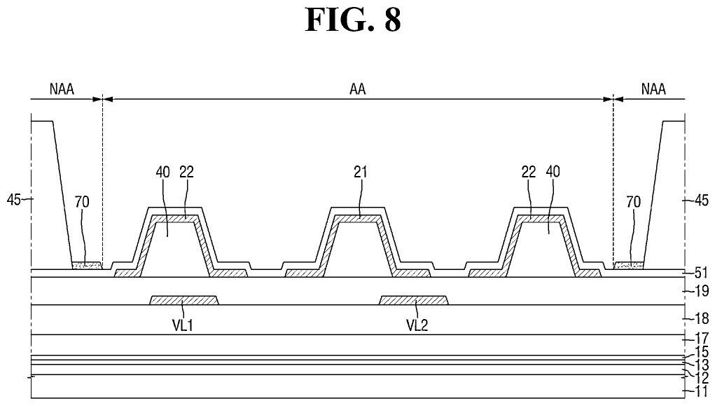

Thereafter, referring to FIG. 8, an alignment-inducing layer 70, which is disposed on parts of the first insulating layer 51, is formed on the first insulating layer 51. The alignment-inducing layer 70 may be disposed on the first insulating layer 51, in regions other than regions between the electrodes 21 and 22. The alignment-inducing layer 70 may be spaced apart in part from outermost electrodes OE, which are disposed on the outermost sides from the center area of each subpixel PXn.

In an embodiment, the alignment-inducing layer 70 may be formed as a self-assembled monolayer (SAM). The SAM may be formed by self-assembling monomolecules on a target surface. The alignment-inducing layer 70 may be formed by depositing monomolecules having a hydrophobic property on the first insulating layer 51 and bonding the monomolecules with each other. The formation of the alignment-inducing layer 70 may be performed by depositing monomolecules having a hydrophobic property on the first insulating layer 51. For example, the monomolecules of the alignment-inducing layer 70 may be bonded with each other and may also be bonded with the material of the first insulating layer 51. For example, in a case where the first insulating layer 51 includes SiOₓ, a hydroxyl group (—OH) bonded with silicon (Si) may be exposed on the surface of the first insulating layer 51. For example, the alignment-inducing layer 70 may be formed by depositing the monomolecules, for example, Si(CH₃)₃)₂NH, which is obtained from the hydroxyl group (—OH) on the surface of the first insulating layer 51. For example, Si(CH₃)₃)₂NH, which is a monomolecular material that forms the alignment-inducing layer 70, may be bonded with oxygen exposed on the surface of the first insulating layer 51, and the alignment-inducing layer 70 may form a monolayer including the Si(CH₃)₃)₂NH bonded with the oxygen. The alignment-inducing layer 70, which is formed as a monolayer including Si(CH₃)₃)₂NH, may have a hydrophobic property.

However, the formation of the alignment-inducing layer 70 is not limited thereto. In some embodiments, the alignment-inducing layer 70 may be obtained by forming a monolayer on the entire surface of the first insulating layer 51 and modifying the surface of the monolayer.

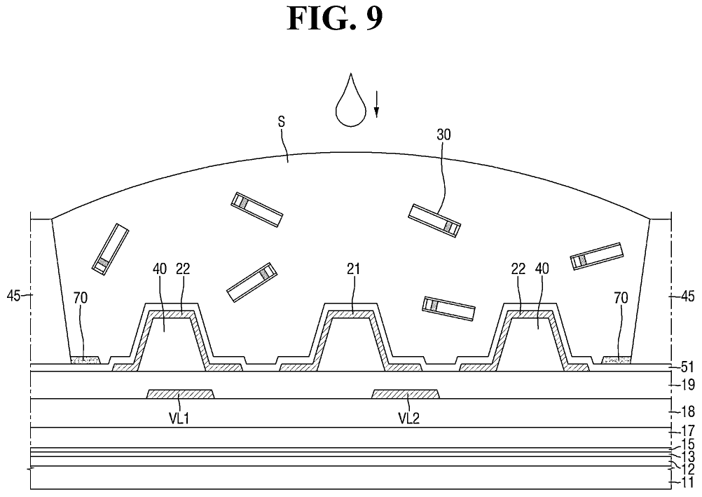

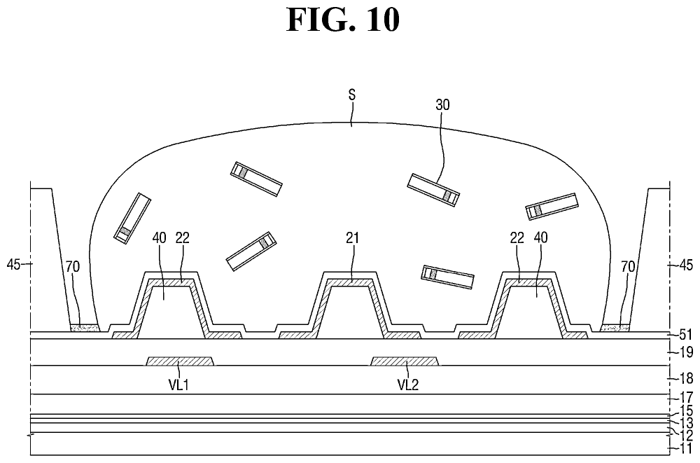

Thereafter, referring to FIGS. 9 and 10, ink S including light-emitting elements 30 is sprayed into a region surrounded by the second bank 45, on the target substrate SUB. The light-emitting elements 30, which are dispersed in the solvent of the ink S, may be sprayed on the target substrate SUB. In an embodiment, the light-emitting elements 30 may be prepared in a state of being dispersed in the ink S and may be sprayed onto the target substrate SUB through printing by using an inkjet printing device.

The ink S sprayed through printing using the inkjet printing device may spread evenly and settle in the region surrounded by the second bank 45. The second bank 45 may prevent the ink S from spilling or overflowing over between different subpixels PXn. Some of the ink S may settle in a region where the alignment-inducing layer 70 is formed, and some of the ink S may settle in a region where the alignment-inducing layer 70 is not formed.

The display device 10 may guide the ink S including the light-emitting elements 30 dispersed therein to move to (or settle at) a targeted location. As already mentioned above, the solvent of the ink S may be hydrophilic, and the alignment-inducing layer 70 may include a hydrophobic material. In a case where a hydrophilic solvent settles on the alignment-inducing layer 70 including a hydrophobic material, the ink S may move to a region where the alignment-inducing layer 70 is not disposed, because of a chemical repulsion between the hydrophilic solvent and the hydrophobic material.

The solvent of the ink S may form interfaces not only with the first insulating layer 51, the electrodes 21 and 22, and the alignment-inducing layer 70, but also with the air. The solvent may move such that the surface energy of the interfaces is minimized, and the interface formed by a hydrophilic solvent with the hydrophobic alignment-inducing layer 70 has a high surface energy. The solvent of the ink S may have a movement to minimize the area of the interface formed with the alignment-inducing layer 70, and the ink S sprayed onto the target substrate SUB may move to (and settle in) the region where the alignment-inducing layer 70 is not disposed.

Accordingly, the ink S including the light-emitting elements 30 dispersed therein may move to (or settle in) the region where the alignment-inducing layer 70 is not formed, e.g., the regions between the electrodes 21 and 22. Most of the light-emitting elements 30 may be disposed later on the electrodes 21 and 22, in areas that do not overlap the alignment-inducing layer 70.

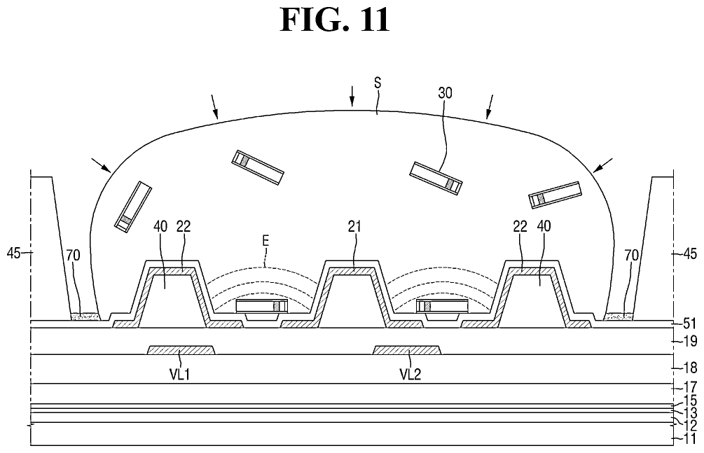

Referring to FIG. 11, the light-emitting elements 30 may be disposed on the electrodes 21 and 22 by applying alignment signals to the electrodes 21 and 22. As the alignment signals are applied to the electrodes 21 and 22, an electric field may be generated on the ink S sprayed on the electrodes 21 and 22. In case that the electric field is generated on the electrodes 21 and 22, the light-emitting elements 30 dispersed in the ink S may receive a force from the electric field. For example, the orientation directions and positions of the light-emitting elements 30 may continue to change, and the light-emitting elements 30 may be seated on the first electrode 21 and the second electrodes 22.

Due to the alignment-inducing layer 70, the ink S may move to a certain location, and most of the light-emitting elements 30 may be disposed on the electrodes 21 and 22, in the region that the ink S is moved to. The light-emitting elements 30 may be aligned between the first electrode 21 and the second electrodes 22 such that end portions (e.g., opposite end portions) thereof may be connected (e.g., electrically connected) to the first electrode 21 and the second electrodes 22. The alignment-inducing layer 70 may surround the region where the electrodes 21 and 22 are spaced apart from each other, and the light-emitting elements 30 may be aligned between the electrodes 21 and 22. Light-emitting elements 30 disposed in regions other than between the electrodes 21 and 22 may not be electrically connected to the first electrode 21 or the second electrodes 22 and may eventually fail to emit light in the display device 10. These light-emitting elements 30 may be lost in each subpixel PXn. The alignment-inducing layer 70 may guide the ink S to move between the electrodes 21 and 22 and may minimize the number of light-emitting elements 30 that fail to be electrically connected to the electrodes 21 and 22 and are lost.

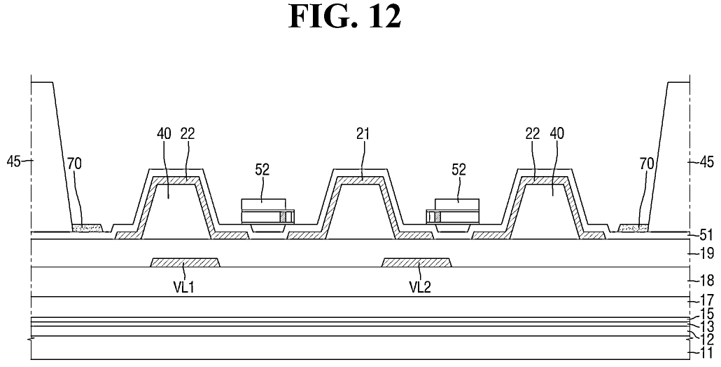

Thereafter, referring to FIG. 12, in case that the light-emitting elements 30 are aligned between the electrodes 21 and 22, the solvent of the ink S may be removed, and a second insulating layer 52 may be formed. The removal of the solvent may be performed by a typical thermal treatment process or a typical light irradiation process. The thermal treatment process or the light irradiation process may be performed to selectively remove the solvent without damaging the light-emitting elements 30. The second insulating layer 52 may fix the light-emitting elements 30 aligned between the electrodes 21 and 22. In case that the second insulating layer 52 is formed, the initially-aligned locations of the light-emitting elements 30 may be changed later.

For example, connecting electrodes 26 and 27, a third insulating layer 53, and a fourth insulating layer 54 may be formed, thereby obtaining the display device 10.

The formation of the display device 10 may include forming the alignment-inducing layer 70 and guiding the ink S including the light-emitting elements 30 dispersed therein to certain locations. The light-emitting elements 30 may be densely arranged in the region where the alignment-inducing layer 70 is formed, e.g., in an alignment area AA. As the display device 10 includes the alignment-inducing layer 70, the number of light-emitting elements 30 that are lost during the fabrication of the display device 10 may be minimized, and the degree of emission concentration may be improved by densely arranging the light-emitting elements 30 at a certain location.

Display devices 10 according to embodiments will hereinafter be described.

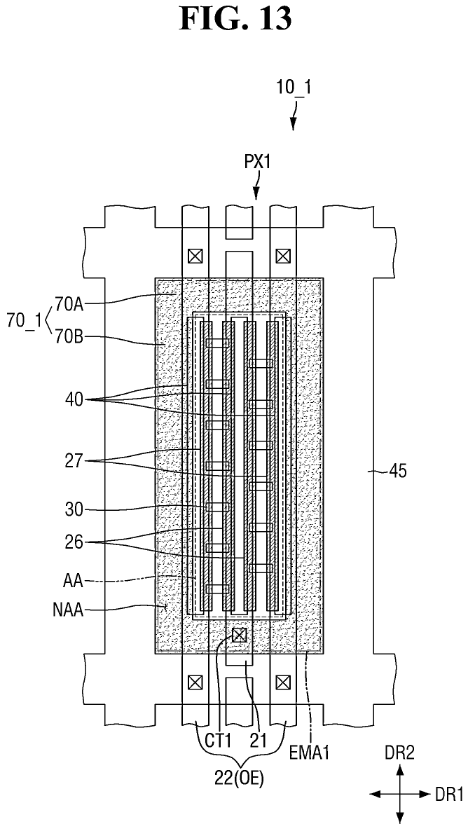

FIG. 13 is a schematic plan view of a subpixel of a display device 10_1 according to an embodiment.

Referring to a display device 10_1 of FIG. 13, an alignment-inducing layer 70_1 may partially cover outermost electrodes OE along a direction in which the outermost electrodes OE extend. For example, the alignment-inducing layer 70_1 may intersect electrodes 21 and 22, and second extensions 70B may cover the outer sides of the outermost electrodes OE. The embodiment of FIG. 13 differs from the embodiment of FIG. 2 in the layout of the alignment-inducing layer 70_1. The embodiment of FIG. 13 will hereinafter be described, focusing on the differences with the embodiment of FIG. 2.

At least one end portion of each of light-emitting elements 30 may be disposed on a first electrode 21 or one of second electrodes 22, and the light-emitting elements 30 may be aligned in a direction between the first electrode 21 and the second electrodes 22. As the light-emitting elements 30 are aligned between the electrodes 21 and 22, the alignment-inducing layer 70_1 may be disposed such that ink S including the light-emitting elements 30 dispersed therein may be positioned between the electrodes 21 and 22 during the fabrication of the display device 10_1. The alignment-inducing layer 70_1 may cover outer sides of outermost electrodes OE, for example, sides of the outermost electrodes OE that are spaced apart from each other, and face a second bank 45. An alignment area AA where the alignment-inducing layer 70_1 is not disposed may be positioned to include spaces between the electrodes 21 and 22, and the light-emitting elements 30 may be disposed between the electrodes 21 and 22, in the alignment area AA.

The second extensions 70B of the alignment-inducing layer 70_1 may partially overlap the electrodes 21 and 22 and first banks 40, which extend in a second direction DR2. As the alignment-inducing layer 70_1 partially covers the outermost electrodes OE in the second direction DR2, the display device 10_1 may guide the ink S including the light-emitting elements 30 dispersed therein to settle in (or move to) the regions between the electrodes 21 and 22.

As already mentioned above, the alignment-inducing layer 70 may include not only part including a hydrophobic material, but also part including a hydrophilic material. Parts of the alignment-inducing layer 70 having the same chemical polarity as the ink S may be disposed between the electrodes 21 and 22 to form the alignment area AA, and parts of the alignment-inducing layer 70 having a different chemical polarity from the ink S may be disposed in the rest of the subpixel PXn to form the non-alignment area NAA.

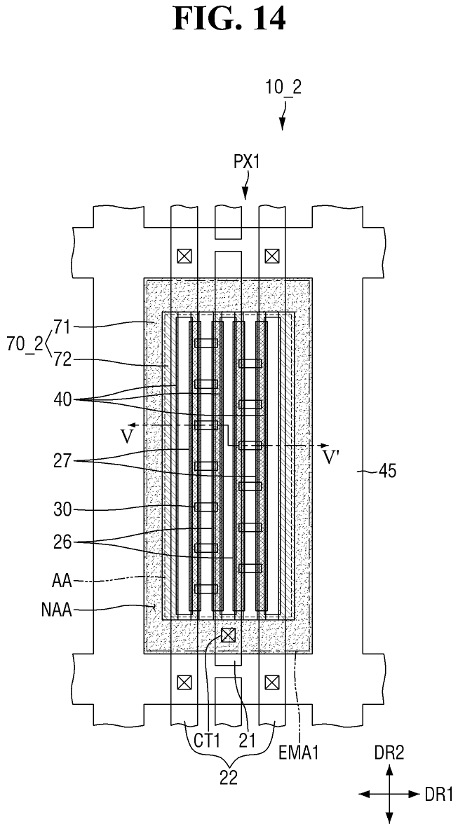

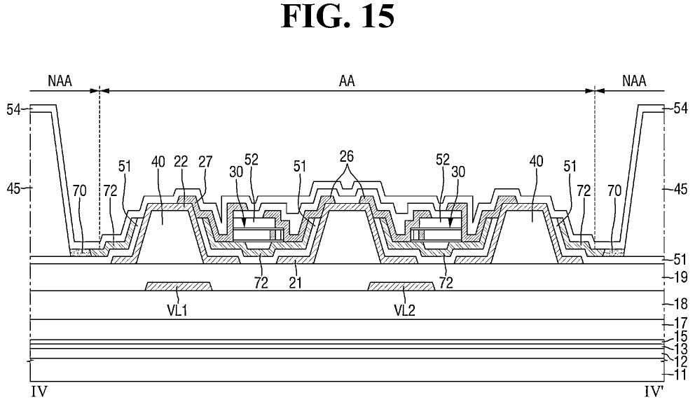

FIG. 14 is a schematic plan view of a subpixel PXn of a display device 10_2 according to an embodiment. FIG. 15 is a schematic cross-sectional view taken along line V-V′ of FIG. 14.

Referring to FIGS. 14 and 15, an alignment-inducing layer 70_2 of a display device 10_2 may include a first part 71, which includes a hydrophilic material, and a second part 72, which includes a hydrophilic material. The alignment-inducing layer 70_2 may be disposed in an entire region surrounded by a second bank 45, in a subpixel PXn, the second part 72 may be disposed between electrodes 21 and 22, and the first part 71 may be disposed in the rest of the subpixel PXn. The alignment-inducing layer 70_2 of the display device 10_2 may include part having the same chemical polarity as ink S including light-emitting elements 30 dispersed therein and part having a different chemical polarity from the ink S and may thus be able to effectively guide the ink S to settle in (or move to) certain locations.

The alignment-inducing layer 70_2 may include the first part 71 and the second part 72 and may be disposed on substantially on the entire surface of the subpixel PXn to expose the upper surfaces of the electrodes 21 and 22. For example, the alignment-inducing layer 70_2 and a first insulating layer 51 may be arranged in the same shape. For example, the first part 71 of the alignment-inducing layer 70_2 may not overlap the light-emitting elements 30, and the second part 72 of the alignment-inducing layer 70_2 may overlap the light-emitting elements 30.

The first part 71 of the alignment-inducing layer 70_2 may include a hydrophobic material and may partially surround regions between the electrodes 21 and 22. The second part 72 may be disposed on part of the subpixel PXn where the first part 71 is not disposed, mostly in the regions between the electrodes 21 and 22. The second part 72, like the first insulating layer 51, may be disposed between the electrodes 21 and 22 to cover a region where the electrodes 21 and 22 are spaced apart from each other, and face each other. In an embodiment, the light-emitting elements 30 may be disposed (e.g., directly disposed) on the second part 72 of the alignment-inducing layer 70_2, but not on the first part 71. An alignment area AA and a non-alignment area NAA of the subpixel PXn may correspond to the second part 72 and the first part 71, respectively, of the alignment-inducing layer 70_2.

The alignment-inducing layer 70_2 may be formed by depositing a hydrophobic material and a hydrophilic material, but embodiments are not limited thereto. In an embodiment, the alignment-inducing layer 70_2 may be formed by depositing a material whose surface characteristics changes upon the irradiation of light and performing a mask process that applies light.

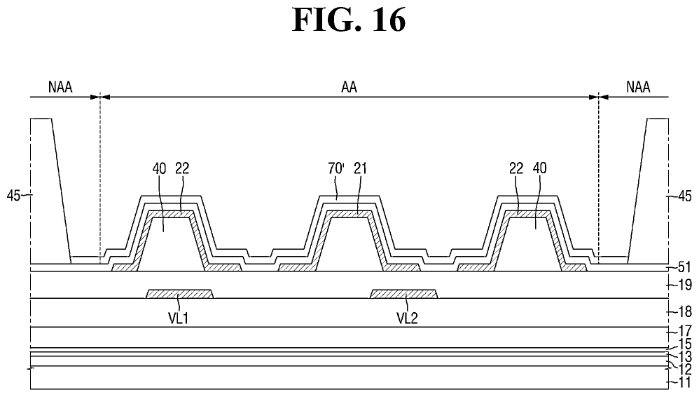

FIGS. 16 through 18 are schematic cross-sectional views illustrating a method of manufacturing the display device 10_2 of FIG. 14.

Referring to FIG. 16, a base layer 70′ is formed on a target substrate where first banks 40, electrodes 21 and 22, and a first insulating layer 51 are formed. The base layer 70′ may form an alignment-inducing layer 70_2, which is partially hydrophilic and partially hydrophobic, later through surface treatment. A method to treat the surface of the base layer 70′ is not limited thereto. A hydrophilic or hydrophobic material may be deposited on the surface of the base layer 70′, or the surface of the base layer 70′ may be modified through plasma treatment.

In an embodiment, the base layer 70″ may include a photo-induced surface control (PISC) material whose surface is modified by applying light, and the formation of the alignment-inducing layer 70_2 may include applying light only to certain regions. The base layer 70′ may become hydrophilic or hydrophobic in response to light being applied thereto, and the alignment-inducing layer 70_2 may be formed by a light irradiation process by using a mask.

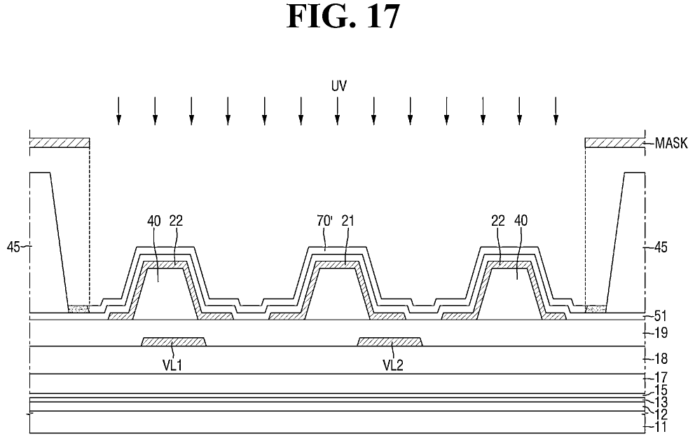

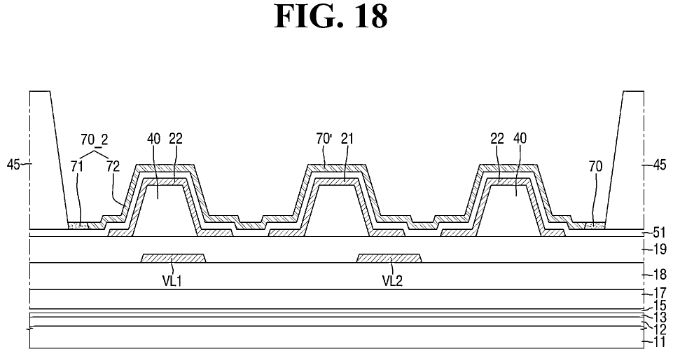

Referring to FIGS. 17 and 18, a mask “MASK” may be disposed on the base layer 70′, and the alignment-inducing layer 70_2, which has different chemical polarities from an area to another area, is formed by applying light UV. The base layer 70′ may be surface-modified by the light UV and may thus become chemically hydrophilic or hydrophobic, and part of the base layer 70′ irradiated with the light UV and part of the base layer 70′ not irradiated with the light UV may have different properties. In an embodiment, the base layer 70′ may include a hydrophobic material, and the part of the base layer 70′ irradiated with the light UV may be modified to have a hydrophilic property. During the formation of the alignment-inducing layer 70_2, the mask “MASK”, which is used for surface modification through the irradiation of the light UV, may be disposed to correspond to a region where light-emitting elements 30 are to be disposed, for example, regions between the electrodes 21 and 22.

Part of the base layer 70′ that overlaps the regions between the electrodes 21 and 22 may be irradiated with the light UV and may thus have a hydrophilic property, and the rest of the base layer 70′ may not be irradiated with the light UV and may thus have a hydrophobic property. The alignment-inducing layer 70_2 may include first and second parts 71 and 72 according to which part of the alignment-inducing layer 70_2 is irradiated with the light UV and may form an alignment area AA where the light-emitting elements 30 are densely arranged. As the alignment-inducing layer 70_2 includes the first part 71, which is hydrophobic, and the second part 72, which is hydrophilic, a region that ink S is guided to settle in or move to during the fabrication of the display device 10_2 may be clearly distinguished. As a result, the number of light-emitting elements 30 that are lost due to being disposed in the non-alignment area NAA may be further reduced.

As the display device 10 includes the alignment-inducing layer 70, the light-emitting elements 30 may be densely arranged in the region defined by the alignment-inducing layer 70, and each subpixel PXn may include the alignment area AA and the non-alignment area NAA. To electrically connect the light-emitting elements 30 to the electrodes 21 and 22, the alignment area AA may include the regions between the electrodes 21 and 22, and the non-alignment area NAA may not include the regions between the electrodes 21 and 22. In some embodiments, parts of the regions between the electrodes 21 and 22 may correspond to the alignment area AA, and parts of the regions between the electrodes 21 and 22 may correspond to the non-alignment area NAA. For example, each subpixel PXn may include multiple alignment areas AA according to the layout of the alignment-inducing layer 70, and a non-alignment area NAA may be disposed between the multiple alignment areas AA. For example, a pixel region overlapping (or corresponding to) each subpixel PXn may include the multiple alignment areas AA and the non-alignment area NAA, which is adjacent to multiple alignment areas AA and surrounds the multiple alignment areas AA.

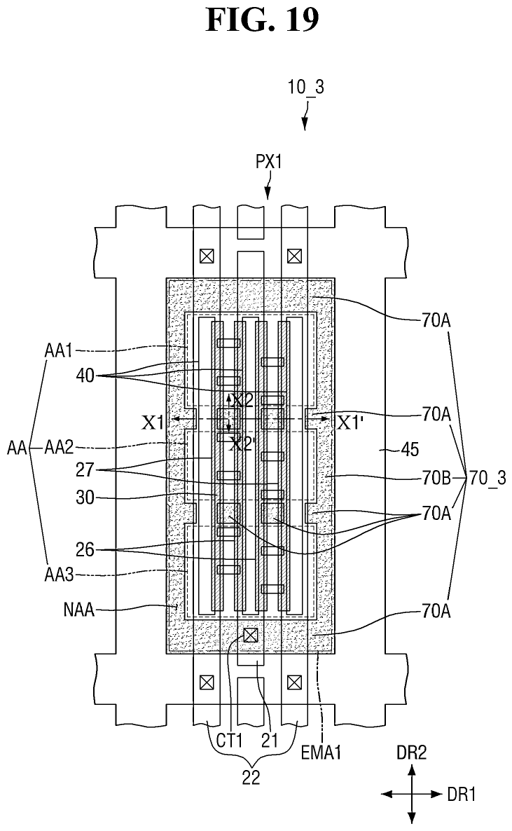

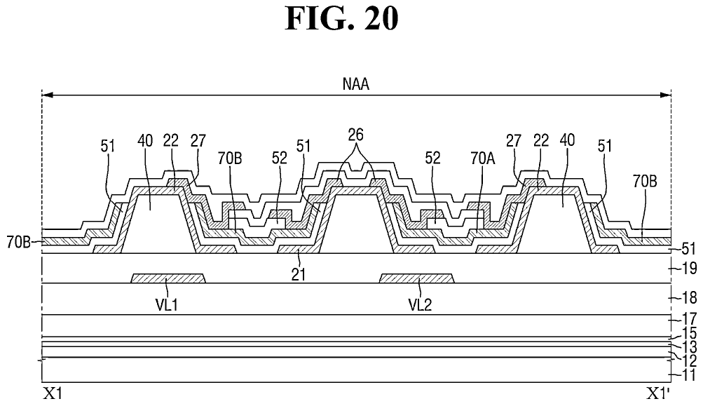

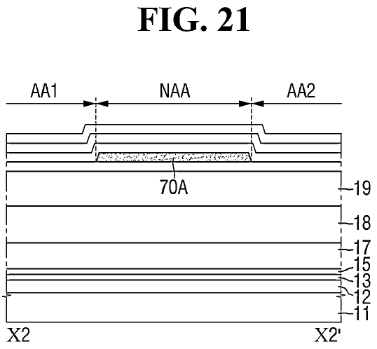

FIG. 19 is a schematic plan view of a subpixel of a display device 10_3 according to an embodiment. FIG. 20 is a schematic cross-sectional view taken along line X1-X1′ of FIG. 19. FIG. 21 is a schematic cross-sectional view taken along line X2-X2′ of FIG. 19. FIG. 20 is a schematic cross-sectional view, taken along a first direction DR1, of a non-alignment area NAA between two adjacent alignment areas AA, and FIG. 21 is a schematic cross-sectional view, taken along a second direction DR2, of the non-alignment area NAA between the two adjacent alignment areas AA.

Referring to FIGS. 19 through 21, in a display device 10_3, an alignment-inducing layer 70_3 may be disposed in part even in regions between electrodes 21 and 22, in a subpixel PXn. An emission area EMA of the subpixel PXn may include alignment areas AA, and the alignment-inducing layer 70_3 may be disposed between the alignment areas AA to form a non-alignment area NAA. The embodiment of FIGS. 19 through 21 differs from the embodiment of FIG. 2 in that the alignment-inducing layer 70_3 forms a relatively large number of alignment areas AA in each subpixel PXn. The embodiment of FIGS. 19 through 21 will hereinafter be described, focusing on the differences with the embodiment of FIG. 2.

The alignment-inducing layer 70_3 may surround first banks 40 or the regions between the electrodes 21 and 22 and may be disposed at least in part between the electrodes 21 and 22. The alignment-inducing layer 70_3 may include first extensions 70A, and the first extensions 70A may extend in the first direction DR1 across the electrodes 21 and 22 extending in the second direction DR2. Some of the first extensions 70A of the alignment-inducing layer 70_3 may extend across the first banks 40 to be disposed in part between the electrodes 21 and 22. For example, some of the first extensions 70A of the alignment-inducing layer 70_3 may be disposed between the first and second alignment areas AA1 and AA2 and between the second and third alignment areas AA2 and AA3, and may be spaced apart from each other in the first direction DR1. Accordingly, the alignment-inducing layer 70_3 may divide the regions between the electrodes 21 and 22, and alignment areas AA may be formed in the region surrounded by the alignment-inducing layer 70_3.

The layout of the alignment-inducing layer 70_3 may be obtained by forming the first extensions 70A to extend across the first banks 40 and removing parts of the first extensions 70A during the exposure of the upper surfaces of the electrodes 21 and 22. Accordingly, parts of the first extensions 70A that extend across the first banks 40 on the upper surfaces of the electrodes 21 and 22 may remain removed in the regions between the electrodes 21 and 22.

The alignment areas AA may include the regions between the electrodes 21 and 22 and may be arranged in a direction between the electrodes 21 and 22. For example, the alignment areas AA of the subpixel PXn may include first, second, and third alignment areas AA1, AA2, and AA3, and the first, second, and third alignment areas AA1, AA2, and AA3 may be arranged in the second direction DR2. The alignment-inducing layer 70_3 may be disposed between the alignment areas AA to form the non-alignment area NAA.

As each subpixel PXn includes multiple alignment areas AA, multiple regions in which the light-emitting elements are densely arranged may be formed between the electrodes 21 and 22. Due to the alignment-inducing layer 70_3, the alignment areas AA may include the regions between the electrodes 21 and 22, but in a case where only one alignment area AA is disposed in each subpixel PXn to have a large area, the light-emitting elements 30 may be arranged at a high density, only in part of the emission area EMA.

For example, according to the embodiment of FIG. 2, the alignment-inducing layer 70 may be disposed in the regions between the electrodes 21 and 22 or around the first banks 40 to form the alignment area AA, and the alignment area AA may have a large area. Light-emitting elements 30 may be arranged at an arbitrary distribution in the alignment area AA. The light-emitting elements 30 may be densely arranged only in part of the alignment area AA and may thus have an irregular distribution. The subpixel PXn where the light-emitting elements 30 are unevenly distributed may have different light emission amounts from a location to another location in the emission area EMA.

In the display device 10_3 of FIG. 19, the alignment-inducing layer 70_3 may partially surround the regions between the electrodes 21 and 22 so that each subpixel PXn may include multiple alignment areas AA. The multiple alignment areas AA may have a relatively small size, and light-emitting elements 30 disposed in each of the multiple alignment areas AA may have a uniform distribution. Accordingly, each subpixel PXn of the display device 10_3 may emit a uniform amount of light without any discrepancy in the amount of light emitted from a location to another location in an emission area EMA.

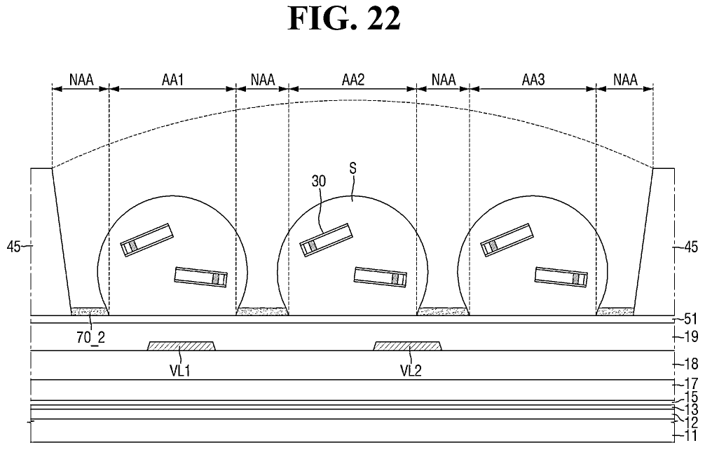

FIG. 22 is a schematic cross-sectional view illustrating a method of manufacturing the display device 10_3 of FIG. 19. FIG. 22 is a schematic cross-sectional view, taken along a second direction DR2, of a region where first extensions 70A of an alignment-inducing layer 70_3 of the display device 10_3 of FIG. 19 are arranged.

Referring to FIG. 22, as the alignment-inducing layer 70_3 of the display device 10_3 partially surrounds regions between electrodes 21 and 22, alignment areas AA may be formed. During the fabrication of the display device 10_3, as ink S including light-emitting elements 30 dispersed therein is sprayed into each subpixel PXn, the ink S may settle in (or move to) a region where the alignment-inducing layer 70_3 is not disposed. As the alignment-inducing layer 70_3 divides each subpixel PXn into regions, the ink S sprayed into each subpixel PXn may settle in (or move to) each of the plurality of regions. The ink S may include a uniform distribution of light-emitting elements 30, and light-emitting elements 30 may be arranged at a uniform distribution in each of the alignment areas AA, which are separated by the alignment-inducing layer 70_3. As the display device 10_3 includes multiple alignment areas AA, any discrepancy in the emission of light from each subpixel PXn may be minimized.

For example, at least one end portion of each of the light-emitting elements 30, which are disposed between the electrodes 21 and 22, may be connected (e.g., electrically connected) to the first electrode 21. As the light-emitting elements 30 are connected (e.g., electrically connected) to the first electrode 21, the light-emitting elements 30 may be connected (e.g., electrically connected) in parallel to each other. In case that one of the light-emitting elements 30 is defective and the first electrode 21 and the second electrodes 22 are short-circuited due to the defective light-emitting element 30, electrical signals applied to the first electrode 21 and the second electrodes 22 may flow only through the defective light-emitting element 30. In case that the light-emitting elements 30 are connected in parallel, a subpixel PXn may not be able to emit light because of the short circuit of the light-emitting elements 30. To address this, the display device 10 may divide each subpixel PXn into alignment areas AA via the alignment-inducing layer 70 and may connect light-emitting elements 30 in series in each of the alignment areas AA.

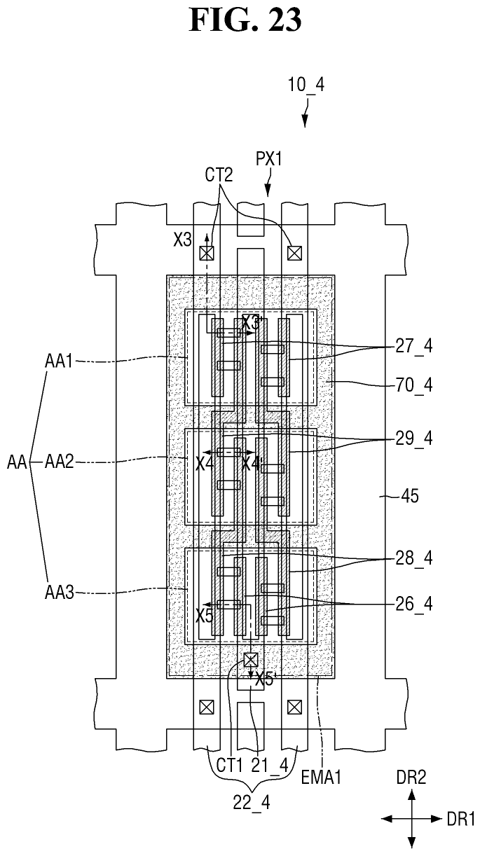

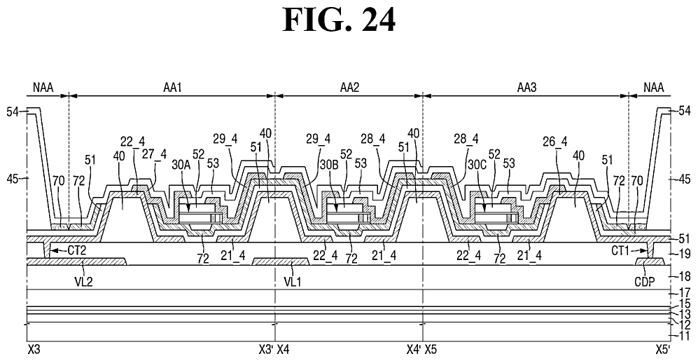

FIG. 23 is a schematic plan view of a subpixel PXn of a display device 10_4 according to an embodiment. FIG. 24 is a schematic cross-sectional view taken along lines X3-X3′, X4-X4′, and X5-X5′ of FIG. 23. FIG. 24 is a schematic cross-sectional view taken from an end portion to the other end portion of each of light-emitting elements (30A, 30B, and 30C) disposed in first, second, and third alignment areas AA1, AA2, and AA3.

Referring to FIGS. 23 and 24, each subpixel PXn of a display device 10_4 may include alignment areas AA, e.g., first, second, and third alignment areas AA1, AA2, and AA3, and different sets of connecting electrodes 26_4, 27_4, 28_4, and 29_4 may be disposed in the alignment areas AA. The display device 10_4 differs from its counterpart of FIG. 19 in that it includes connecting electrodes 26_4, 27_4, 28_4, and 29_4 having different structures. The embodiment of FIGS. 23 and 24 will hereinafter be described, focusing on the differences with the embodiment of FIG. 19.

An alignment-inducing layer 70_4 of the display device 10_4 of FIG. 23 may have the same shape as its counterpart of the display device 10_3 of FIG. 19. The alignment-inducing layer 70_4 may be disposed in each subpixel PXn to surround some regions in each subpixel PXn. Regions defined by the alignment-inducing layer 70_4 may form alignment areas AA. For example, each subpixel PXn may include first, second, and third alignment areas AA1, AA2, and AA3.

Light-emitting elements 30 may be disposed in each of the alignment areas AA and may be in contact with the connecting electrodes 26_4, 27_4, 28_4, and 29_4, which are disposed in the alignment areas AA. The light-emitting elements 30 may include first light-emitting elements 30A, which are disposed in the first alignment area AA1, second light-emitting elements 30B, which are disposed in the second alignment area AA2, and third light-emitting elements 30C, which are disposed in the third alignment area AA3. End portions of the first light-emitting elements 30A, the second light-emitting elements 30B, and the third light-emitting elements 30C may be connected (e.g., electrically connected) to the same connecting electrodes 26_4, 27_4, 28_4, and 29_4 and may be connected in parallel to each other.

The display device 10_4 may include first connecting electrodes 26_4 and second connecting electrodes 27_4, which are connected to one of electrodes 21_4 and 22_4 and an end portion of each of the light-emitting elements 30, and third connecting electrodes 28_4 and fourth connecting electrodes 29_4, which are in contact not with the electrodes 21_4 and 22_4, but with an end portion of each of the light-emitting elements 30.

The first connecting electrodes 26_4 may be disposed in the third alignment area AA3 and may be in contact with a first electrode 21_4 and first end portions of the third light-emitting elements 30C. The first connecting electrodes 26_4 may transmit electrical signals applied to the first electrode 21_4, which is in contact with a first conductive pattern CDP in a first contact hole CT1, to the first end portions of the third light-emitting elements 30C. The first connecting electrodes 26_4 may extend in a second direction DR2 and may be disposed in the third alignment area AA3. Two separate first connecting electrodes 26_4 may be disposed in the third alignment area AA3.

The second connecting electrodes 27_4 may be disposed in the first alignment area AA1 and may be in contact with second electrodes 22_4 and second end portions of the first light-emitting elements 30A. The second connecting electrodes 27_4 may transmit electrical signals applied to the second electrodes 22_4, which are in contact with a second voltage line VL2 in second contact holes CT2, to the second end portions of the first light-emitting elements 30A. The second connecting electrodes 27_4 may extend in the second direction DR2 and may be disposed in the first alignment area AA1. Two separate second connecting electrodes 27_4 may be disposed in the first alignment area AA1.

The first connecting electrodes 26_4 and the second connecting electrodes 27_4 may be disposed in the alignment areas AA and may be in contact with end portions of the light-emitting elements 30 and with the electrodes 21_4 and 22_4. The display device 10_4 may further include the third connecting electrodes 28_4 and the fourth connecting electrodes 29_4, which are disposed in multiple alignment areas and are in contact only with the light-emitting elements 30, in addition to the first connecting electrodes 26_4 and the second connecting electrodes 27_4.

The third connecting electrodes 28_4 may be in contact with first end portions of the first light-emitting elements 30A, which are disposed in the first alignment area AA1, and second end portions of the second light-emitting elements 30B, which are disposed in the second alignment area AA2. The fourth connecting electrodes 29_4 may be in contact with first end portions of the second light-emitting elements 30B, which are disposed in the second alignment area AA2, and second end portions of the third light-emitting elements 30C, which are disposed in the third alignment area AA3. The third connecting electrodes 28_4 may include parts extending in the second direction DR2 and parts extending in a first direction DR1. The parts of the third connecting electrodes 28_4 that extend in the second direction DR2 may be disposed in the first and second alignment areas AA1 and AA2, and the parts of the third connecting electrodes 28_4 that extend in the first direction DR1 may connect the parts of the third connecting electrodes 28_4 that extend in the second direction DR2 and may be disposed in the first and second alignment areas AA1 and AA2. The fourth connecting electrodes 29_4 and the third connecting electrodes 28_4 may have substantially the same shape. For example, the fourth connecting electrodes 29_4 may be disposed in the second and third alignment areas AA2 and AA3. Two separate third connecting electrodes 28_4 and two separate fourth connecting electrodes 29_4 may be disposed in each subpixel PXn.

The third connecting electrodes 28_4 and the fourth connecting electrodes 29_4 may not be connected (e.g., directly connected) to the electrodes 21_4 and 22_4, but may be connected (e.g., electrically connected) to the electrodes 21_4 and 22_4 through the light-emitting elements 30. Electrical signals applied from the second electrodes 22_4 through the second connecting electrodes 27_4 may be transmitted to the second light-emitting elements 30B through the first light-emitting elements 30A and the third connecting electrodes 28_4. The electrical signals may be transmitted to the third light-emitting elements 30C through the second light-emitting elements 30B and the fourth connecting electrodes 29_4. For example, electrical signals applied from the second electrodes 22_4 through the first connecting electrodes 26_4 may be transmitted to the second light-emitting elements 30B through the third light-emitting elements 30C and the fourth connecting electrodes 29_4. The electrical signals may be transmitted to the first light-emitting elements 30A through the second light-emitting elements 30B and the third connecting electrodes 28_4. As the light-emitting elements 30, which are disposed in the alignment areas AA of each subpixel PXn, are connected (e.g., electrically connected) through connecting electrodes 26_4, 27_4, 28_4, and 29_4, the first light-emitting elements 30A, the second light-emitting elements 30B, and the third light-emitting elements 30C, which are disposed in the first, second, and third alignment areas AA1, AA2, and AA3, respectively, may be connected to each other in series.

If one of the first light-emitting elements 30A is short-circuited, no electrical signals may be transmitted to the first light-emitting elements 30A, which are disposed in the first alignment area AA1. However, as electrical signals still may be transmitted to the light-emitting elements disposed in each of the second and third alignment areas AA2 and AA3, light still may be emitted. For example, the display device 10_4 may include, in each subpixel PXn, light-emitting elements 30, which are disposed in one of alignment areas AA and are connected in series. Thus, in case that one of the plurality of light-emitting elements 30 is defective, the display device 10_4 still may emit light via the other light-emitting elements 30. For example, as the plurality of light-emitting elements 30 are connected in series, the emission efficiency of the display device 10_4 may be further improved.

For example, each of first electrodes 21 may be in contact with a first conductive pattern CDP through a first contact hole CT1 and may thus be connected (e.g., electrically connected) to a driving transistor DT. Light-emitting elements 30 disposed between one first electrode 21 and one second electrode 22 may form parallel connections with light-emitting elements 30 disposed between the other first electrode 21 and the second electrode 22, but embodiments are not limited thereto. In some embodiments, the display device 10 may further include electrodes that are not directly connected to circuit elements disposed below the first planarization layer 19, and light-emitting elements 30 disposed between the electrodes may form serial connections.

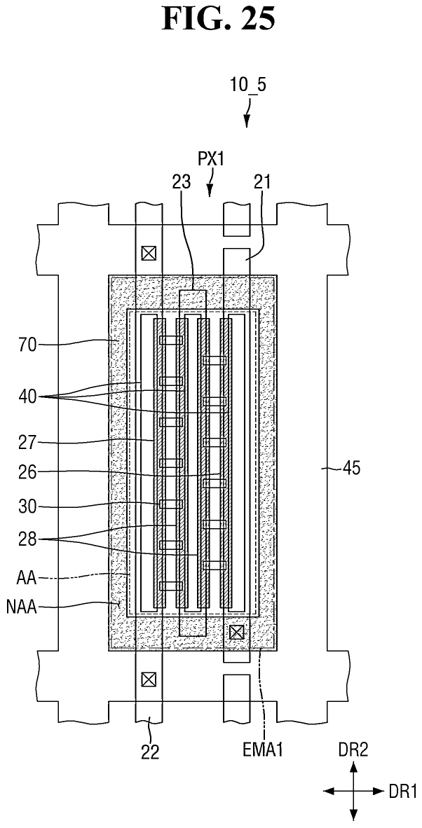

FIG. 25 is a schematic plan view of a subpixel of a display device 10_5 according to an embodiment.

Referring to FIG. 25, a display device 10_2 may further include first and second electrodes 21 and 22 and may further include a third electrode 23, which is disposed between the first and second electrodes 21 and 22. For example, connecting electrodes 26, 27, and 28 may further include a third connecting electrode 28, which is disposed on the third electrode 23. A first bank 40 may be disposed between the third electrode 23 and a first planarization layer 19, and light-emitting elements 30 may be disposed between the first and third electrodes 21 and 23 and between the third and second electrodes 23 and 22. The display device 10_5 differs from its counterpart of FIG. 2 in that each subpixel PXn further includes the third electrode 23 and the third connecting electrode 28. The third electrode 23 will be described below.

The third electrode 23 may be disposed between the first and second electrodes 21 and 22. First banks 40, for example, three first banks 40, may be disposed on the first planarization layer 19, and the first, third, and second electrodes 21, 23, and 22 may be sequentially arranged on the first banks 40. The third electrode 23 may extend in a second direction DR2. The third electrode 23, unlike the first and second electrodes 21 and 22, may extend in the second direction DR2, but may not overlap parts of a second bank 45 extending in a first direction DR1. For example, the third electrode 23 may be spaced apart from the parts of the second bank 45. For example, the length, in the second direction DR2, of the third electrode 23 may be less than the length of the first and second electrodes 21 and 22, and the third electrode 23 may not extend beyond the boundary areas with neighboring subpixels PXn.

The light-emitting elements 30 may be disposed between the first and third electrodes 21 and 23 and between the third and second electrodes 23 and 22. The third connecting electrode 28 and first and second connecting electrodes 26 and 27 may have the same shape. For example, the third connecting electrode 28 may be disposed on the third electrode 23. One first connecting electrode 26 and one second connecting electrode 27 may be disposed in each subpixel PXn, and multiple third connecting electrodes 27 may be disposed in each subpixel PXn. However, embodiments are not limited thereto.

Light-emitting elements 30 disposed between the first and third electrodes 21 and 23 may be in contact with the first and third connecting electrodes 26 and 28 and may thus be connected (e.g., electrically connected) to the first and third electrodes 21 and 23. Light-emitting elements 30 disposed between the third and second electrodes 23 and 22 may be in contact with the third and second connecting electrodes 28 and 27 and may thus be connected (e.g., electrically connected) to the third and second electrodes 22 and 22.

The third electrode 23, unlike the first and second electrodes 21 and 22, may not be directly connected to a circuit element layer through a contact hole. Electrical signals applied to the first and second electrodes 21 and 22 may be transmitted to the third electrode 23 through the first and second connecting electrodes 26 and 27 and the light-emitting elements 30. For example, the light-emitting elements 30 disposed between the first and third electrodes 21 and 23 may form serial connections with the light-emitting elements 30 disposed between the third and second electrodes 23 and 22. As the display device 10_5 further includes the third electrode 23, serial connections between the light-emitting elements 30 may be configured. Thus, the emission efficiency of each subpixel PXn may be further improved.

For example, the electrodes 21 and 22 of the display device 10 may not extend in a direction. The shapes of the electrodes 21 and 22 are not limited thereto, as long as they are spaced apart from each other, and face each other to form a region in which to arrange the light-emitting elements 30. In some embodiments, the electrodes 21 and 22 may have a curved shape, and one of the electrodes 21 and 22 may surround the other electrodes.

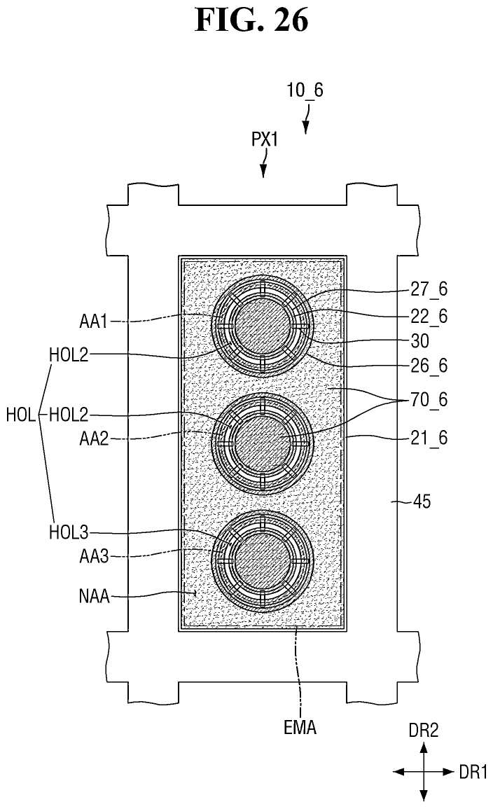

FIG. 26 is a schematic plan view of a subpixel of a display device 10_6 according to an embodiment.

Referring to FIG. 26, at least parts of a first electrode 21_6 and second electrodes 22_6 of a display device 10_6 may have a curved shape, and curved parts of the first electrode 21_6 may be spaced apart from each other, and may face curved parts of the second electrodes 22_6. The display device 10_6 of FIG. 26 differs from the display device 10 of FIG. 2 in the shapes of the first electrode 21_6 and the second electrodes 22_6. The embodiment of FIG. 26 will hereinafter be described, focusing on the differences with the embodiment of FIG. 2.

The first electrode 21_6 may be disposed on the entire surface of a subpixel PXn and may include holes HOL. For example, the first electrode 21_6 may include first, second, and third holes HOL1, HOL2, and HOL3, which are arranged along a second direction DR2, but embodiments are not limited thereto. In another example, the first electrode 21_6 may include more than three holes HOL, less than three holes HOL, or only one hole HOL. The first electrode 21_6 will hereinafter be described as including the first, second, and third holes HOL1, HOL2, and HOL3.

In an embodiment, the first, second, and third holes HOL1, HOL2, and HOL3 may have a circular shape in a plan view. Accordingly, the first electrode 21_6 may have curved regions formed by the holes HOL and may face the second electrodes 22_6 in the curved regions, but embodiments are not limited thereto. The shape of the first, second, and third holes HOL1, HOL2, and HOL3 is not limited thereto as long as the first, second, and third holes HOL1, HOL2, and HOL3 provide space in which to arrange the second electrodes 22_6. For example, the first, second, and third holes HOL1, HOL2, and HOL3 may have an elliptical shape or a polygonal shape such as a rectangular shape in a plan view.

Second electrodes 22_6 may be disposed in the subpixel PXn. For example, three second electrodes 22_6 may be disposed in the subpixel PXn to correspond to the first, second, and third holes HOL1, HOL2, and HOL3 of the first electrode 21_6. The second electrodes 22_6 may be positioned in the first, second, and third holes HOL1, HOL2, and HOL3 to be surrounded by the first electrode 21_6.

In an embodiment, the holes HOL of the first electrode 21_6 may have a curved shape, and the second electrodes 22_6 may have a curved shape, may be spaced apart from the first electrode 21_6, and may face the first electrode 21_6. The first electrode 21_6 may include the holes HOL, which have a circular shape in a plan view, and the second electrodes 22_6 may have a circular shape in a plan view. Curved sides of the first electrode 21_6 in the holes HOL may be spaced apart from each other, and may face curved outer sides of the second electrodes 22_6. For example, the first electrode 21_6 may surround the outer sides of the second electrodes 22_6.

An alignment-inducing layer 70_6 may cover the first electrode 21_6 and the second electrodes 22_6, but may expose the gaps between the first electrode 21_6 and the second electrodes 22_6. For example, the alignment-inducing layer 70_6 may expose parts of the subpixel PXn where the first electrode 21_6 and the second electrodes 22_6 are spaced apart from each other, and face each other, but cover the rest of the subpixel PXn. Accordingly, alignment areas AA may be formed in regions between the first electrode 21_6 and the second electrodes 22_6 where the alignment-inducing layer 70_6 is not disposed, and a non-alignment area NAA may be formed in the rest of the subpixel PXn.

Light-emitting elements may be disposed in the alignment areas AA between the first electrode 21_6 and the second electrodes 22_6. At least one end portion of each of the light-emitting elements 30 may be disposed on the parts of the subpixel PXn where the first electrode 21_6 and the second electrodes 22_6 are spaced apart from each other, and face each other. As the alignment-inducing layer 70_6 is not disposed in the parts of the subpixel PXn where the first electrode 21_6 and the second electrodes 22_6 are spaced apart from each other, and face each other, ink S may settle in (or move to) the regions between the first electrode 21_6 and the second electrodes 22_6. The light-emitting elements 30 may be disposed in the regions between the first electrode 21_6 and the second electrodes 22_6, where the alignment-inducing layer 70 is not disposed.

First connecting electrodes 26_6 and second connecting electrodes 27_6 may be in contact with first end portions of the light-emitting elements 30, the first electrode 21_6, or the second electrodes 22_6. The first connecting electrodes 26_6 may be disposed along the holes HOL of the first electrode 21_6 and may have a circular arc shape with a thickness in a plan view. The second connecting electrodes 27_6 may cover the second electrodes 22_6 and may have a circular shape in a plan view. However, embodiments are not limited thereto. In some embodiments, the first connecting electrodes 26_6 and the first electrode 21_6 may have substantially the same shape. The second connecting electrodes 27_6 and the second electrodes 22_6 may have substantially the same shape. For example, the first connecting electrodes 26_6 and the second connecting electrodes 27_6 may correspond only to parts of the subpixel PXn where the light-emitting elements 30, the first electrode 21_6, and the second electrodes 22_6 are in contact with each other.

The display device 10_6 may include the second electrodes 22_6, which have a circular shape, and the first electrode 21_6, which surrounds the second electrodes 22_6, and the light-emitting elements 30 may be arranged along the curved outer sides of the second electrodes 22_6. As the light-emitting elements 30 extend in a direction, and the light-emitting elements 30, which are arranged along the curved outer sides of the second electrodes 22_6, may be arranged to be oriented in different directions. The subpixel PXn may emit light in various directions according to the directions faced by the light-emitting elements 30. As the first electrode 21_6 and the second electrodes 22_6 of the display device 10_6 have a curved shape, the light-emitting elements 30, which are disposed between the first electrode 21_6 and the second electrodes 22_6, may be arranged to face different directions, and the side visibility of the display device 10_6 may be improved.

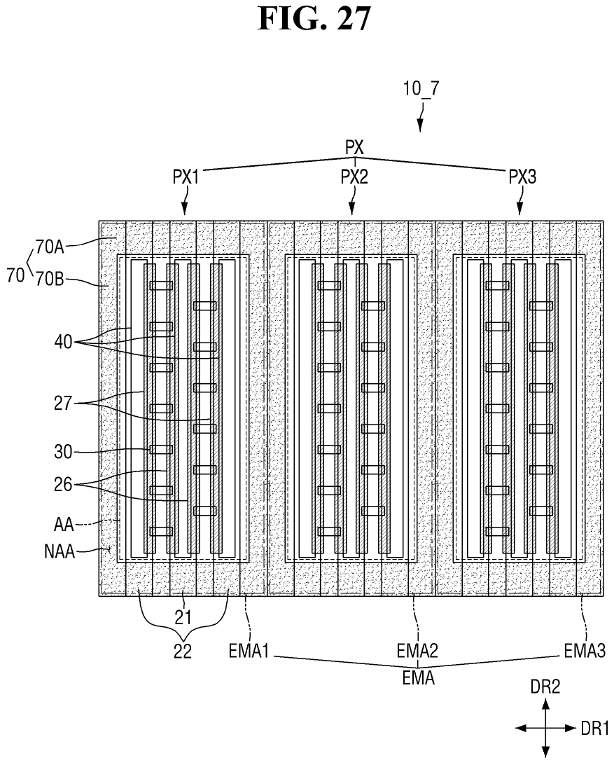

FIG. 27 is a schematic plan view of a pixel PX of a display device 10_7 according to an embodiment. For descriptive convenience, FIG. 27 illustrates the layout of subpixels PXn and the layout of an alignment-inducing layer 70.

Referring to FIG. 27, a display device 10_7 may not include a second bank 45. The second bank 45 may not only define the boundary areas between neighboring subpixels PXn, but also prevent ink S from spilling or overflowing over between the neighboring subpixels PXn during the fabrication of the display device 10_7. The display device 10_7 may include the alignment-inducing layer 70 and may guide ink S to settle in (or move to) certain locations. In case that the ink S including light-emitting elements 30 dispersed therein is sprayed into a region defined by the alignment-inducing layer 70, the ink S may move to certain locations due to a chemical reaction between the ink S and the alignment-inducing layer 70. In case that the ink S is precisely sprayed at each certain location, the ink S may be prevented from spilling or overflowing over between the neighboring subpixels PXn, due to the presence of the alignment-inducing layer 70. The display device 10_7 may not include the second bank 45, and the alignment-inducing layer 70 may prevent the ink S from spilling or overflowing over to other subpixels PXn. As the second bank 45 is not provided, the fabrication of the display device 10_7 may be simplified, and the area of each subpixel PXn may be reduced. Thus, a high-resolution display device may be readily implemented.

For example, the display device 10 may include the alignment-inducing layer 70 and may separate different regions, for example, different subpixels PXn, without the aid of a structure. As the ink S sprayed into each certain region may move to the region defined by the alignment-inducing layer 70, a structure such as the second bank 45 may be omitted.

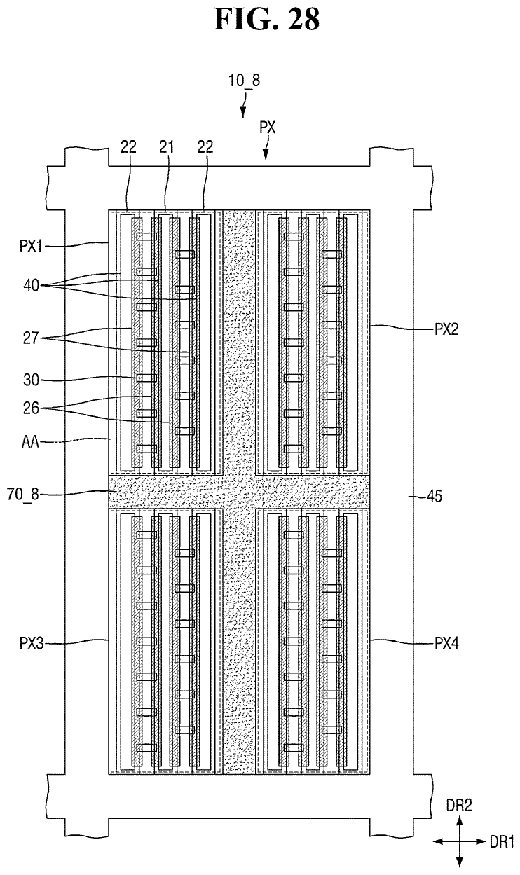

FIG. 28 is a schematic plan view of a subpixel PXn of a display device 10_8 according to an embodiment.

Referring to FIG. 28, a display device 10_8 may include subpixels PXn (where n is an integer of 1 to 4) in a region surrounded by a second bank 45. The second bank 45 may surround a pixel PX, and the pixel PX may include subpixels PXn, which are separated from each other by an alignment-inducing layer 70_8.

The alignment-inducing layer 70_8 may extend in first and second directions DR1 and DR2, in the pixel PX surrounded by the second bank 45. Regions defined by the alignment-inducing layer 70_8 and the second bank 45 may become the subpixels PXn. First, second, third, and fourth subpixels PX1, PX2, PX3, and PX4 may be disposed in the region surrounded by the second bank 45. The boundary areas between the first, second, third, and fourth subpixels PX1, PX2, PX3, and PX4 may be defined by the alignment-inducing layer 70_8, and a structure such as the second bank 45 may not be disposed between the first, second, third, and fourth subpixels PX1, PX2, PX3, and PX4. Each of the subpixels PXn may include electrodes 21 and 22, first banks 40, and light-emitting elements 30 and may emit light of a certain wavelength band. In an embodiment, at least some of the first, second, third, and fourth subpixels PX1, PX2, PX3, and PX4 may include sets of light-emitting elements emitting light of different colors, and may thus emit light of different colors, but embodiments are not limited thereto. The subpixels PXn in the pixel PX may include sets of light-emitting elements 30 emitting light of the same color.

In a case where the subpixels PXn are separated by a structure in the region surrounded by the second bank 45, ink S may require to be precisely sprayed into each region defined by the structure. As the size of the subpixels PXn becomes smaller, the rate of error may be increased in case that the ink S is sprayed into each certain region, and the amount of the ink S disposed in untargeted regions may be increased. However, in a case where the subpixels PXn are separated by the alignment-inducing layer 70_8, rather than by a structure, as in the display device 10_8 of FIG. 28, the ink S may be guided to settle in (or move to) each targeted region due to the alignment-inducing layer 70_8, in case that there is error in the ejection position of the ink S. For example, as the display device 10_8 includes the alignment-inducing layer 70_8, the size of each region separated by the alignment-inducing layer 70_8 or the size of the subpixels PXn may be reduced. In case that error occurs in connection with the ejection of the ink S, the ink S including the light-emitting elements 30 dispersed therein may be precisely guided at each target location. The display device 10_8 may improve a process margin for the ejection of the ink S and may be advantageous for realizing an ultrahigh-resolution display device having small subpixels PXn.

In concluding the detailed description, those skilled in the art will appreciate that many variations and modifications may be made to the preferred embodiments without substantially departing from the principles of the invention. Therefore, the disclosed preferred embodiments of the invention are used in a generic and descriptive sense only and not for purposes of limitation.

1. A display device comprising:
a pixel region including a plurality of alignment areas and a non-alignment area adjacent to the plurality of alignment areas;
a plurality of electrodes extending in a direction in the pixel region, the plurality of electrodes spaced apart from each other;
a plurality of light-emitting elements disposed between the plurality of electrodes in the plurality of alignment areas, at least one end portion of each of the plurality of light-emitting elements disposed on one of the plurality of electrodes; and
an alignment-inducing layer including a first part disposed in the non-alignment area.

2. The display device of claim 1, wherein
the first part of the alignment-inducing layer includes a hydrophobic material, and
the first part surrounds the plurality of alignment areas.

3. The display device of claim 2, further comprising:
a plurality of connecting electrodes disposed in the plurality of alignment areas, the plurality of connecting electrodes overlaying the plurality of electrodes and end portions of the plurality of light-emitting elements.

4. The display device of claim 2, wherein the first part of the alignment-inducing layer partially covers electrodes disposed on outermost sides of the pixel region and extends along the direction.

5. The display device of claim 2, wherein
the plurality of alignment areas include a first alignment area and a second alignment area that are spaced apart from each other in the direction, and
the alignment-inducing layer including extension parts disposed between the first alignment area and the second alignment area.

6. The display device of claim 5, wherein a number of light-emitting elements disposed in the first alignment area and the second alignment area is greater than a number of light-emitting elements disposed between the first alignment area and the second alignment area.

7. The display device of claim 5, wherein the extension parts of the alignment-inducing layer between the first alignment area and the second alignment area are spaced apart from each other.

8. The display device of claim 2, wherein
the alignment-inducing layer further includes a second part including a hydrophilic material, and
the second part is further disposed in the plurality of alignment areas.

9. The display device of claim 8, wherein the plurality of light-emitting elements are disposed directly on the second part of the alignment-inducing layer in the plurality of alignment areas.

10. The display device of claim 1, further comprising:
a plurality of first banks disposed in the pixel region, the plurality of first banks spaced apart from each other and overlapping the plurality of electrodes,
wherein the alignment-inducing layer surrounds the first banks.

11. The display device of claim 10, further comprising:
a second bank surrounding the pixel region and the alignment-inducing layer.

12. The display device of claim 11, wherein
the plurality of alignment areas are spaced apart from each other in a region surrounded by the second bank,
the alignment-inducing layer is disposed between the plurality of alignment areas,
the plurality of light-emitting elements are disposed in the plurality of alignment areas, and
light-emitting elements disposed in different alignment areas emit light of different wavelengths.

13. A display device comprising:
a substrate;
a plurality of first banks disposed on the substrate and spaced apart from each other;
a plurality of electrodes disposed on the first banks and spaced apart from each other;
an alignment-inducing layer disposed on the substrate, the alignment-inducing layer including a first part disposed in regions other than between the plurality of electrodes; and
a plurality of light-emitting elements disposed between the plurality of electrodes, each of the plurality of light-emitting elements including an end portion disposed on the plurality of electrodes,
wherein the first part of the alignment-inducing layer does not overlap the plurality of light-emitting elements.

14. The display device of claim 13, wherein
the first part of the alignment-inducing layer includes a hydrophobic material.

15. The display device of claim 14, wherein the first part of the alignment-inducing layer covers outer sides of electrodes on outermost sides of the substrate.

16. The display device of claim 14, wherein
the alignment-inducing layer further includes a second part including a material,
the second part is disposed between the plurality of electrodes, and
the plurality of light-emitting elements overlap the second part.

17. The display device of claim 13, further comprising:
a first insulating layer overlapping the plurality of electrodes,
wherein the alignment-inducing layer is disposed on the first insulating layer.

18. The display device of claim 17, further comprising:
a second insulating layer disposed between the plurality of electrodes, the second insulating layer overlapping the plurality of light-emitting elements.

19. The display device of claim 17, wherein the first insulating layer and the alignment-inducing layer expose upper surfaces of the plurality of electrodes on the first banks.

20. The display device of claim 19, further comprising:
a plurality of connecting electrodes in contact with the exposed upper surfaces of the plurality of electrodes and an end portion of each of the plurality of light-emitting elements.
